(19) United States
(12) Patent Application Publication
(10) Pub. No.: US 2014/0077302 A1
(43) Pub. Date: Mar. 20, 2014

(54) POWER RECTIFYING DEVICES

(71) Applicant: ELECTRONICS AND TELECOMMUNICATIONS RESEARCH INSTITUTE, Daejeon (KR)

(72) Inventors: Kunsik PARK, Daejeon (KR); KYOUNG IL NA, Daejeon (KR); Jin Ho LEE, Daejeon (KR); JIN-GUN KOO, Daejeon (KR)

(73) Assignee: Electronics and Telecommunications Research Institute, Daejeon (KR)

(21) Appl. No.: 13/846,701

(22) Filed: Mar. 18, 2013

(30) Foreign Application Priority Data
Sep. 14, 2012 (KR) 10-2012-0102184
Jan. 9, 2013 (KR) 10-2013-0002510

(51) Int. Cl. H01L 29/78

(52) U.S. Cl. CPC H01L 29/78
USPC 257/365; 257/288

(57) ABSTRACT

According to a power rectifying device of embodiments of the inventive concept, a gate electrode, a source region, and a body region are connected in common to a first terminal, and a substrate beside the body region is connected to a second terminal. Thus, the power rectifying device having two terminals is realized. The gate electrode has s spacer-shape. Thus, a width of the gate electrode may be controlled to accurately control a channel length of a channel region of a transistor structure in the power rectifying device.

### CROSS-REFERENCE TO RELATED APPLICATIONS

This U.S. non-provisional patent application claims priority under 35 U.S.C. §119 to Korean Patent Application Nos. 10-2012-0102184 and 10-2013-0002510, filed on Sep. 14, 2012 and Jan. 9, 2013, the entirety of which is incorporated by reference herein.

### BACKGROUND

The inventive concept relates to power rectifying devices and, more particularly, to power rectifying devices using a semiconductor technique.

Power rectifiers for controlling a high voltage and a high power may be applied to various fields such as a power supply and/or a power converter. The power rectifiers may use a P-N junction diode and/or a schottky diode.

The P-N diode has a low leakage current characteristic and excellent reliability at a high temperature. However, the P-N diode has a high forward turn-on voltage (e.g., about 0.7V). Additionally, the P-N diode has a current conduction property using minor carriers. Thus, a switching speed (e.g., a reverse recovery time) of the P-N diode may be slow. On the other hand, the schottky diode has a low forward turn-on voltage by a suitable metal electrode. Additionally, the schottky diode has a current conduction characteristic by major carriers. Thus, a reverse recovery time of the schottky diode may be fast. However, the schottky diode has a large leakage current in off state. Additionally, the schottky diode includes a metal and a semiconductor which are in contact with each other, such that reliability of the schottky diode may be deteriorated at a high temperature.

### SUMMARY

Embodiments of the inventive concept may provide power rectifying devices having a low forward turn-on voltage characteristic.

Embodiments of the inventive concept may also provide power rectifying devices having a fast switching speed.

Embodiments of the inventive concept may also provide power rectifying devices having an excellent leakage current characteristic.

Embodiments of the inventive concept may also provide power rectifying devices having excellent thermal reliability.

In one aspect, a power rectifying device may include: a substrate doped with dopants of a first conductivity type; a first gate electrode disposed on the substrate; a first body region formed in the substrate at a side of the first gate electrode, the first body region doped with dopants of a second conductivity type different from the first conductivity type; a second gate electrode disposed on a sidewall of the first gate electrode and on the first body region; and a source region formed in the first body region at a side of the second gate electrode, the source region doped with dopants of the first conductivity type. The first gate electrode, the second gate electrode, the first body region, and the source region may be connected in common to a first terminal; and the substrate under the first gate electrode may be connected to a second terminal

In an embodiment, the power rectifying device may further include: a gate dielectric pattern disposed between the first gate electrode and the substrate and between the second gate electrode and the substrate. The second gate electrode may be in contact with the sidewall of the first gate electrode.

In an embodiment, the power rectifying device may further include: a first gate dielectric pattern disposed between the first gate electrode and the substrate; and a second gate dielectric pattern disposed between the second gate electrode and the substrate. The second gate dielectric pattern may extend between first gate electrode and the second gate electrode.

In an embodiment, the power rectifying device may further include: a dielectric-spacer disposed between the first and second gate electrodes; a first gate dielectric pattern disposed between the first gate electrode and the substrate; and a second gate dielectric pattern disposed between the second gate electrode and the substrate. The dielectric-spacer may include a different dielectric material from the first and second gate dielectric patterns.

In an embodiment, the first gate dielectric pattern may laterally extend to be disposed between the dielectric-spacer and the substrate.

In an embodiment, the dielectric-spacer may extend downward to be disposed between the first and second gate dielectric patterns.

In an embodiment, a top surface of the first gate electrode may be lower than a top end of the second gate electrode.

In an embodiment, the power rectifying device may further include: a second body region disposed in the substrate under the first body region. The second body region may be doped with dopants of the second conductivity type.

In an embodiment, the second gate electrode may have a first sidewall adjacent to the first gate electrode and a second sidewall opposite to the first sidewall; and the second body region may have a sidewall aligned with the second sidewall of the second gate electrode.

In an embodiment, the second body region may have a sidewall aligned with the sidewall of the first gate electrode.

In an embodiment, the second gate electrode may be formed by performing an etch-back process on a gate layer deposited on the substrate having the first gate electrode.

In another aspect, a power rectifying device may include: a substrate doped with dopants of a first conductivity type; a first gate electrode disposed on the substrate; a gate dielectric pattern disposed between the first gate electrode and the substrate; a pedestal pattern disposed on a top surface of the first gate electrode; a first body region disposed in the substrate at a side of the pedestal pattern, the first body region doped with dopants of a second conductivity type different from the first conductivity type; a second gate electrode disposed on a sidewall of the pedestal pattern and on an edge of the top surface of the first gate electrode, the second gate electrode disposed over the first body region; and a source region disposed in the first body region at a side of the second gate electrode, the source region doped with dopants of the first conductivity type. The first and second gate electrodes, the first body region, and the source region may be connected in common to a first terminal; and the substrate under the first gate electrode may be connected to a second terminal

In an embodiment, the second gate electrode may have a first sidewall adjacent to the pedestal and a second sidewall opposite to the first sidewall; and the first gate electrode may have a sidewall aligned with the second sidewall of the second gate electrode.

In an embodiment, the second gate electrode may be in contact with the edge of the top surface of the first gate electrode.

In an embodiment, the power rectifying device may further include: an etch stop pattern disposed between the pedestal pattern and the first gate electrode. The etch stop pattern may be formed of a dielectric material having an etch selectivity with respect to the pedestal pattern.

In an embodiment, the power rectifying device may further include: a second body region formed in the substrate under the first body region. The second body region may be doped with dopants of the second conductivity type.

In an embodiment, the second gate electrode may be formed by performing an etch-back process on a gate layer deposited on the substrate having the first gate electrode.

In still another aspect, a power rectifying device may include: a substrate doped with dopants of a first conductivity type; an etch stop pattern disposed on the substrate; a body region disposed in the substrate at a side of the etch stop pattern, the body region doped with dopants of a second conductivity type different from the first conductivity type; a gate electrode disposed on a sidewall of the etch stop pattern and on the body region; a gate dielectric pattern disposed between the gate electrode and the body region; and a source region disposed in the body region at a side of the gate electrode, the source region doped with dopants of the first conductivity type. The gate electrode, the body region, and the source region may be connected in common to a first terminal, and the substrate under the etch stop pattern may be connected to a second terminal. The gate electrode may have a first sidewall adjacent to the sidewall of the etch stop pattern, and a second sidewall opposite to the first sidewall. The second sidewall of the gate electrode may include a rounded portion. A top end of the gate electrode may be higher than a top surface of the etch stop pattern.

In an embodiment, the power rectifying device may further include: a surface doped region formed in the substrate under the etch stop pattern. The surface doped region may be doped with dopants of the first conductivity type; and a dopant concentration of the surface doped region may be greater than a dopant concentration of the substrate directly beneath the surface doped region.

In an embodiment, the power rectifying device may further include: a guarding region formed in the substrate at a side of the source region. The guarding region may be doped with dopants of the second conductivity type, and the body region may be connected to the guarding region. A top surface of the guarding region may be recessed to be lower than a top surface of the source region.

### BRIEF DESCRIPTION OF THE DRAWINGS

The inventive concept will become more apparent in view of the attached drawings and accompanying detailed description.

FIG. 1 is a cross-sectional view illustrating a power rectifying device according to some embodiments of the inventive concept;

FIG. 2A is a cross-sectional view illustrating a first modified example of a power rectifying device according to some embodiments of the inventive concept;

FIG. 2B is a cross-sectional view illustrating a second modified example of a power rectifying device according to some embodiments of the inventive concept;

FIG. 2C is a cross-sectional view illustrating a third modified example of a power rectifying device according to some embodiments of the inventive concept;

FIG. 2D is a cross-sectional view illustrating a fourth modified example of a power rectifying device according to some embodiments of the inventive concept;

FIG. 2E is a cross-sectional view illustrating a fifth modified example of a power rectifying device according to some embodiments of the inventive concept;

FIG. 3 is a simulation graph illustrating forward turn-on voltages of power rectifying devices according to some embodiments of the inventive concept;

FIGS. 4A to 4G are cross-sectional views illustrating a method of manufacturing a power rectifying device according to some embodiments of the inventive concept;

FIGS. 5A to 5C are cross-sectional views illustrating a first modified example of a method of manufacturing a power rectifying device according to some embodiments of the inventive concept;

FIGS. 6A to 6C are cross-sectional views illustrating a second modified example of a method of manufacturing a power rectifying device according to some embodiments of the inventive concept;

FIGS. 7A to 7C are cross-sectional views illustrating a third modified example of a method of manufacturing a power rectifying device according to some embodiments of the inventive concept;

FIGS. 8A to 8C are cross-sectional views illustrating a fourth modified example of a method of manufacturing a power rectifying device according to some embodiments of the inventive concept;

FIGS. 9A to 9C are cross-sectional views illustrating a fifth modified example of a method of manufacturing a power rectifying device according to some embodiments of the inventive concept;

FIG. 10 is a cross-sectional view illustrating a power rectifying device according to other embodiments of the inventive concept;

FIG. 11 is a cross-sectional view illustrating a modified example of a power rectifying device according to other embodiments of the inventive concept;

FIGS. 12A to 12H are cross-sectional views illustrating a method of manufacturing a power rectifying device according to other embodiments of the inventive concept;

FIGS. 13A and 13B are cross-sectional views illustrating a modified example of a method of manufacturing a power rectifying device according to other embodiments of the inventive concept;

FIGS. 14A and 14B are graphs illustrating a turn-on characteristic and a turn-off characteristic related to a support pattern in a power rectifying device according to other embodiments of the inventive concept, respectively;

FIGS. 15A and 15B are graphs illustrating a turn-on characteristic and a turn-off characteristic related to a surface doped region in a power rectifying device according to other embodiments of the inventive concept, respectively;

FIGS. 16A and 16B are graphs illustrating a turn-on characteristic and a turn-off characteristic related to a height of a top surface of a guarding region in a power rectifying device according to other embodiments of the inventive concept, respectively;

FIG. 17 is a cross-sectional view illustrating a modified example of a power rectifying device according to still other embodiments of the inventive concept; and

FIGS. 18A to 18D are cross-sectional views illustrating a method of manufacturing a power rectifying device according to still other embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

### First Embodiment

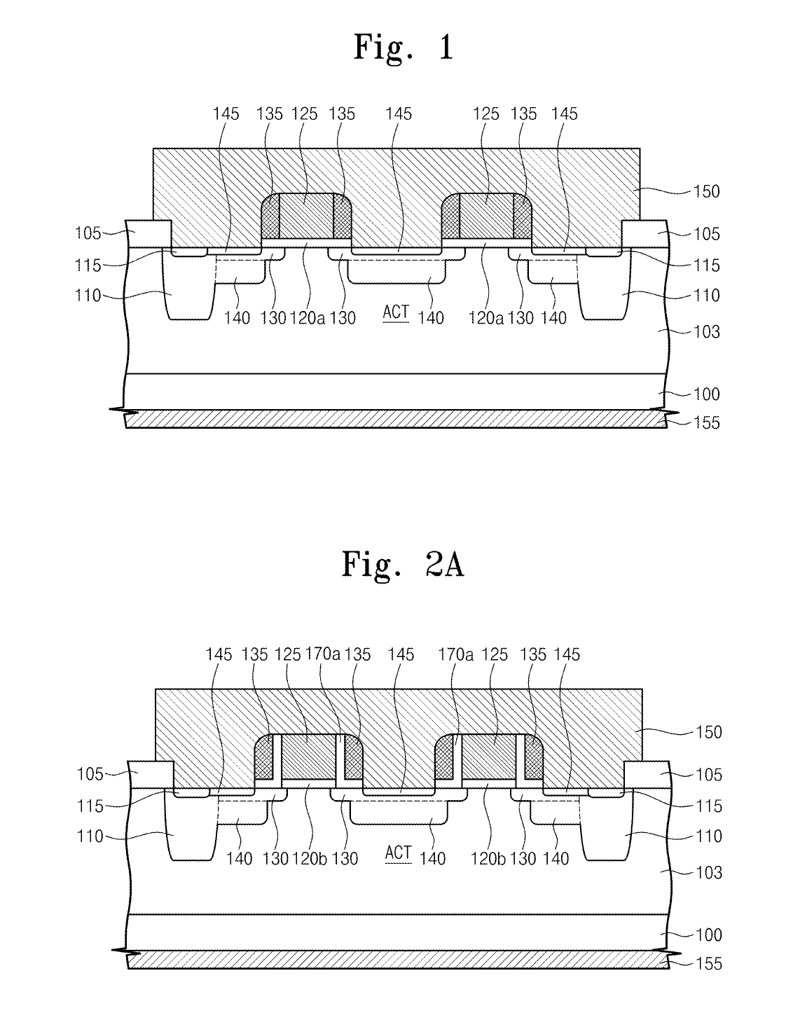

FIG. 1 is a cross-sectional view illustrating a power rectifying device according to some embodiments of the inventive concept.

Referring to FIG. 1, a substrate is provided. The substrate may be doped with dopants of a first conductivity type. In an embodiment, the substrate of the first conductivity type may include a semiconductor substrate 100 and an epitaxial layer 103 disposed on a top surface of the semiconductor substrate 100. For example, the semiconductor substrate 10 may be a silicon substrate, and the epitaxial layer 130 may be a silicon layer. The semiconductor substrate 100 is doped with dopants of the first conductivity type and the epitaxial layer 103 is also doped with dopants of the first conductivity type. In this case, a dopant concentration of the semiconductor substrate 100 may be higher than a dopant concentration of the epitaxial layer 103. However, the inventive concept is not limited to the substrate including the semiconductor substrate 100 and the epitaxial layer 103. In other embodiments, the substrate of the first conductivity type may be a bulk semiconductor substrate doped with dopants of the first conductivity type or may be realized as one of other shapes. Hereinafter, the substrate including the semiconductor substrate 100 and the epitaxial layer 103 will be described as an example for the purpose of ease and convenience in explanation.

A guarding region 110 and a plug region (not shown) may be disposed in the epitaxial layer 103 (i.e., the substrate of the first conductivity type). The guarding region 110 defines an active region ACT. For example, the guarding region 110 may have a depth of about 1 μm to about 10 μm. The active region ACT may be a portion of the epitaxial layer 103 which is surrounded by the guarding region 110. Thus, the active region ACT is doped with the dopants of the first conductivity type. The active region ACT is electrically connected to the substrate 100 thereunder. The guarding region 110 is doped with dopants of a second conductivity type different from the first conductivity type. In an embodiment, a pickup region 115 may be disposed in an upper portion of the guarding region 110. The pickup region 115 is doped with dopants of the second conductivity type, like the guarding region 110. A dopant concentration of the pickup region 115 may be greater than a dopant concentration of the guarding region 110.

A field insulating layer 105 may be disposed on the epitaxial layer 130 outside the active region ACT. The field insulating layer 105 may be formed of silicon oxide. The field insulating layer 150 may have a thickness of about 100 nm to about 1000 nm.

In an embodiment, when an operating voltage of the power rectifying device is equal to or less than about 40V (volt), the guarding region 110 may be omitted. In this case, the active region ACT may be defined by the field insulating layer 105. However, the inventive concept is not limited thereto. In another embodiment, even though the operating voltage of the power rectifying device is equal to or less than about 40V, the guarding region 110 may be disposed in the epitaxial layer 103.

A first gate electrode 125 is disposed on the active region ACT. The first gate electrode 125 is spaced apart upward from the active region ACT. In an embodiment, the first gate electrode 125 may have a thickness of about 50 nm to about 1000 nm.

A first body region 130 is disposed in the active region ACT at each side of the first gate electrode 125. The first body region 130 is doped with dopants of the second conductivity type. In other words, the first body region 130 has the same conductivity type as the guarding region 110. The first body region 130 may be connected to the guarding region 110. The first gate electrode 125 may overlap with an end portion of the first body region 130 which is adjacent to the first gate electrode 125.

The first gate electrode 125 is formed of a conductive material. For example, the first gate electrode 125, a semiconductor material doped with dopants, for example, doped poly-silicon. However, the inventive concept is not limited thereto. In other embodiments, the first gate electrode 125 may include at least one of other conductive materials (e.g., a metal, a metal silicide, and a conductive metal nitride).

A second gate electrode 135 is disposed on each sidewall of the first gate electrode 125 and on the first body region 130. In other words, the second gate electrodes 135 may be disposed on both sidewalls of the first gate electrode 125, respectively. The second gate electrode 135 is spaced apart upward from the first body region 130. The second gate electrode 135 may have a spacer-shape disposed on the sidewall of the first gate electrode 125. For example, the second gate electrode 135 may have a first sidewall adjacent to the sidewall of the first gate electrode 125 and a second sidewall opposite to the first sidewall. The first sidewall of the second gate electrode 135 may be substantially vertically flat along the sidewall of the first gate electrode 125. On the other hand, the second sidewall of the second gate electrode 135 may include a rounded portion.

In an embodiment, the second gate electrode 135 may be formed by performing an etch-back process on a gate layer deposited on the substrate having the first gate electrode 125.

In an embodiment, the second gate electrode 135 may be in contact with the sidewall of the first gate electrode 125. In an embodiment, a gate dielectric pattern 120a may be disposed between the first gate electrode 125 and the active region ACT and between the second gate electrode 135 and the first body region 130. In other words, the gate dielectric pattern 120a may be disposed between the first gate electrode 125 and the active region ACT and may laterally extend to be disposed between the second gate electrode 125 and the active region ACT. The gate dielectric pattern 120a has a sidewall aligned with the second sidewall of the second gate electrode 135. For example, the gate dielectric pattern 120a may include an oxide (e.g., silicon oxide). However, the inventive concept is not limited thereto. In another embodiment, the gate dielectric pattern 120a may include another dielectric material. The gate dielectric pattern 120a may have a thickness of about 1 nm to about 100 nm.

The second gate electrode 135 controls a channel region defined in the body region 130 under the second gate electrode 135. The channel region may extend into the end portion of the first body region 130 overlapping with the first gate electrode 125. The first gate electrode 125 may control the channel region in at least the end portion of the first body region 130 overlapping with the first gate electrode 125. A width of the second gate electrode 135 may control a channel length of the channel region.

The second gate electrode 135 is formed of a conductive material. For example, the second gate electrode 135 may include a semiconductor material doped with dopants, for example, doped poly-silicon. However, the inventive concept is not limited thereto. In other embodiments, the second gate electrode 135 may include at least one of other conductive materials (e.g., a metal, a metal silicide, and a conductive metal nitride).

In an embodiment, a plurality of the first gate electrodes 125 may be disposed on the active region ACT, and the second gate electrode 135 may be disposed on the sidewall of each of the first gate electrodes 125 as illustrated in FIG. 1.

In an embodiment, a second body region 140 may be disposed beneath the first body region 130. The second body region 140 is doped with dopants of the same conductivity type as the first body region 130. That is, the second body region 140 is doped with dopants of the second conductivity type. The second body region 140 may be connected to the guarding region 110. The second body region 140 may have a bottom surface higher than a bottom surface of the guarding region 110.

In an embodiment, as illustrated in FIG. 1, one sidewall of the second body region 140 may be aligned with the second sidewall of the second gate electrode 135. In other words, a width of the second body region 140 may be smaller than a width of the first body region 130. However, the inventive concept is not limited thereto.

A source region 145 may be disposed in the first body region 130 at a side of the second gate electrode 135. The source region 145 is doped with dopants of the same conductivity type as the active region ACT. That is, the source region 145 is doped with dopants of the first conductivity type. The source region 145 may be disposed between the pickup region 115 and the channel region.

The channel region is disposed between the source region 145 and the active region ACT (i.e., a portion of the epitaxial layer 103) under the first gate electrode 125. The active region ACT under the first gate electrode 125 corresponds to a drain region. As described above, the active region ACT is electrically connected to the semiconductor substrate 100 under the epitaxial layer 103. Thus, the drain region is also electrically connected to the semiconductor substrate 100. As a result, the drain region may be enlarged into the epitaxial layer 103 and the semiconductor substrate 100 thereunder. The source region 145, the second gate electrode 135 (or the second and first gate electrodes 135 and 125), and the drain region may constitute a field effect transistor (hereinafter, referred to as ‘a transistor structure’).

The source region 145, the first and second gate electrodes 125 and 135, and the first and second body regions 130 and 140 are electrically connected in common to a first terminal, and the drain region is electrically connected to second terminal. In an embodiment, a first electrode 150 may be disposed on the substrate (e.g., the epitaxial layer 103) and may be electrically connected to the source region 145, the first and second gate electrodes 125 and 135, and the first and second body regions 130 and 140. In an embodiment, the first electrode 150 may be in contact with the source region 145, the first and second gate electrodes 125 and 135, and the pickup region 115. Thus, the first electrode 150 may be electrically connected to the first and second body regions 130 and 140 and the guarding region 110 through the pickup region 115.

A second electrode 155 may be disposed on a bottom surface of the semiconductor substrate 100. The second electrode 155 may be in contact with the bottom surface of the semiconductor substrate 100. The second electrode 155 may be electrically connected to the epitaxial layer 103 including the active region ACT through the semiconductor substrate 100. The first electrode 150 and the second electrode 155 may correspond to the first terminal and the second terminal, respectively. As a result, the power rectifying device having two terminals is realized.

One of the first and second conductivity types is an N-type, and the other of the first and second conductivity types is a P-type. If the first conductive type is the N-type and the second conductivity type is the P-type, the transistor structure may be a NMOS transistor structure, the first electrode 150 may be an anode, and the second electrode 155 may be a cathode. Alternatively, if the first conductivity type is the P-type and the second conductivity type is the N-type, the transistor structure may be a PMOS transistor, the first electrode 150 may be a cathode, and the second electrode 155 may be an anode.

For example, if the first conductivity type is the N-type and the second conductivity type is the P-type, a forward current may flow from the first electrode 150 to the second electrode 155. Alternatively, if the first conductivity type is the P-type and the second conductivity type is the N-type, the forward current may flow from the second electrode 155 to the first electrode 150.

The first electrode 150 may include at least one of a metal (e.g., tungsten, aluminum, copper, titanium, and/or tantalum), a conductive metal nitride (e.g., titanium nitride, tantalum nitride, and/or tungsten nitride), and a metal-semiconductor compound (e.g., a metal silicide). The second electrode 155 may include at least one of a metal (e.g., tungsten, aluminum, copper, titanium, and/or tantalum), a conductive metal nitride (e.g., titanium nitride, tantalum nitride, and/or tungsten nitride), and a metal-semiconductor compound (e.g., a metal silicide).

If a forward voltage is applied between the first and second electrodes 150 and 155 of the power rectifying device described above, the channel region of the transistor structure is turned-on. Thus, a forward turn-on voltage of the power rectifying device may be reduced or minimized. Additionally, since the power rectifying device is a current conduction device using major carriers of the transistor structure, a reverse recovery time of the power rectifying device is short. As a result, the power rectifying device may have a fast switching speed, a low leakage current, and excellent thermal reliability at a high temperature.

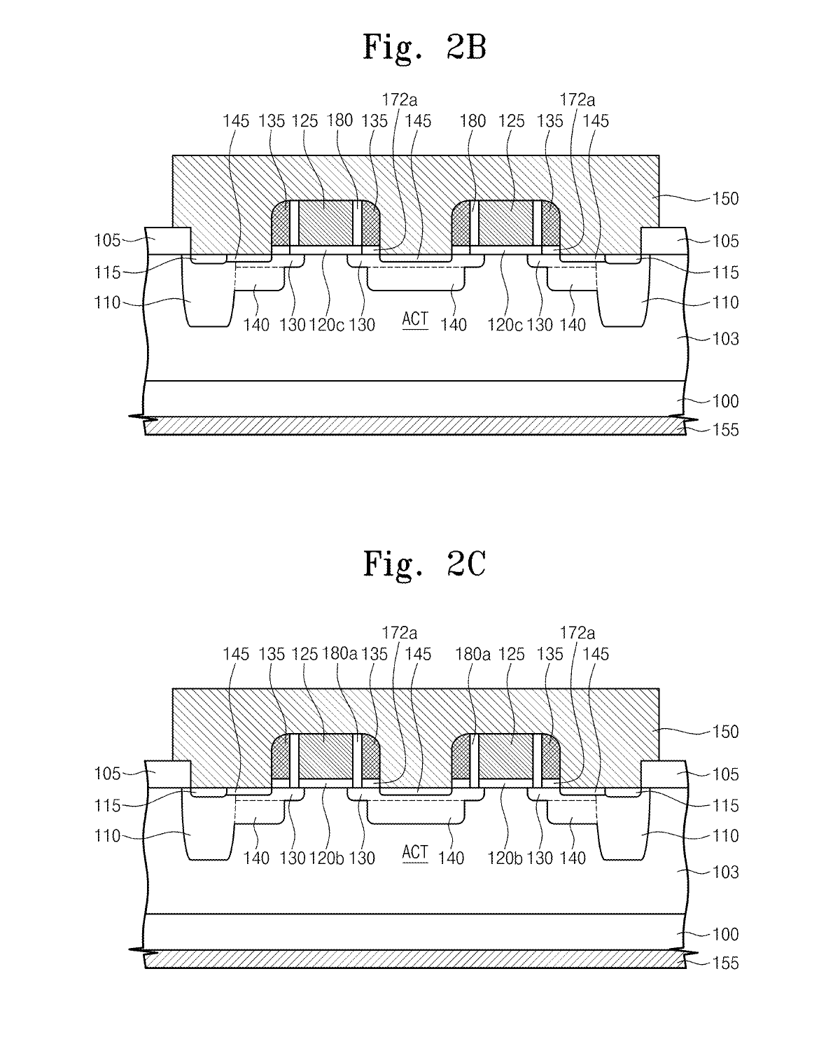

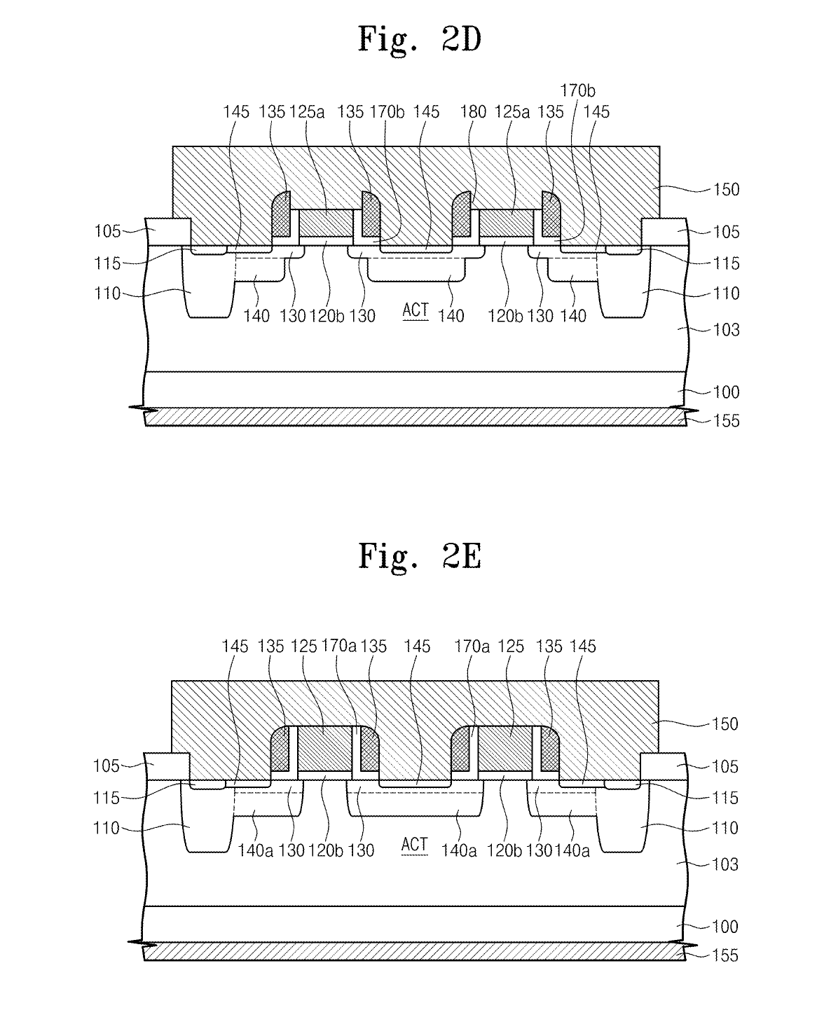

Next, various modified examples of the present embodiment will be described with reference to FIGS. 2A to 2E. In the modified examples, the same elements as described in the aforementioned embodiment will be indicated by the same reference numerals or the same reference designators. For the purpose of ease and convenience in explanation, the descriptions to the same elements as in the aforementioned embodiment will be omitted or mentioned briefly. That is, differences between the modified examples and the aforementioned embodiment will be mainly described hereinafter.

FIG. 2A is a cross-sectional view illustrating a first modified example of a power rectifying device according to some embodiments of the inventive concept.

Referring to FIG. 2A, a first gate dielectric pattern 120b may be confinedly disposed between the first gate electrode 125 and the active region ACT. The first gate dielectric pattern 120b may have both sidewalls which are aligned with both sidewalls of the first gate electrode 125, respectively. A second gate dielectric pattern 170a may be disposed between the second gate electrode 135 and the first body region 130. Additionally, the second gate dielectric pattern 170a may extend to be disposed between the second gate electrode 135 and the first gate electrode 125. In other words, the second gate electrode 135 may be laterally spaced apart from the first gate electrode 125 by the second gate dielectric pattern 170. The second gate dielectric pattern 170a may have a sidewall aligned with the second sidewall of the second gate electrode 135. The second gate dielectric pattern 170a may be in contact with the first gate dielectric pattern 120b. In an embodiment, an interface may exist between the first and second gate dielectric patterns 120b and 170a.

The first gate dielectric pattern 120b may be formed of the same material as the gate dielectric pattern 120a of FIG. 1. For example, the second gate dielectric pattern 170a may be formed of an oxide (e.g., silicon oxide). However, the inventive concept is not limited thereto. In another embodiment, the second gate dielectric pattern 170a may further another dielectric material (e.g., silicon nitride).

FIG. 2B is a cross-sectional view illustrating a second modified example of a power rectifying device according to some embodiments of the inventive concept.

Referring to FIG. 2B, in the present modified example, a dielectric-spacer 180 may be disposed between the first gate electrode 125 and the second gate electrode 135. A first gate dielectric pattern 120c may be disposed between the first gate electrode 125 and the active region ACT. The first gate dielectric pattern 120c may laterally extend to be disposed between the dielectric-spacer 180 and the active region ACT. A second gate dielectric pattern 172a may be disposed between the second gate electrode 135 and the active region ACT (i.e., the first body region 130).

The dielectric-spacer 180 may be formed of a different dielectric material from the first and second dielectric patterns 120c and 172a. For example, the dielectric-spacer may include a nitride (e.g., silicon nitride). The first gate dielectric pattern 120c may include an oxide (e.g., silicon oxide), and the second gate dielectric pattern 172a may include an oxide (e.g., silicon oxide).

FIG. 2C is a cross-sectional view illustrating a third modified example of a power rectifying device according to some embodiments of the inventive concept.

Referring to FIG. 2C, according to the present modified example, the first gate dielectric pattern 120b may be confinedly disposed between the first gate electrode 125 and the active region ACT, and the second gate dielectric pattern 172a may be disposed between the second gate electrode 135 and the active region ACT. A dielectric-spacer 180a may be disposed between the first and second gate electrodes 125 and 135. Additionally, the dielectric-spacer 180a may extend downward to be disposed between the first and second gate dielectric patterns 120b and 172a. The dielectric-spacer 180a may include a different dielectric material from the first and second gate dielectric patterns 120b and 172a. For example, the dielectric-spacer 180a may include a nitride (e.g., silicon nitride).

FIG. 2D is a cross-sectional view illustrating a fourth modified example of a power rectifying device according to some embodiments of the inventive concept.

Referring to FIG. 2D, according to the present modified example, a top surface of a first gate electrode 125a may be lower than a top end of the second gate electrode 135. Likewise, a top end of a second gate dielectric pattern 170b between the first and second gate electrodes 125a and 135 may be lower than the top end of the second gate electrode 135. Thus, the first electrode 150 may also be in contact with the first sidewall of the second gate electrode 135 which is higher than the top surface of the first gate electrode 125a.

In an embodiment, the gate dielectric pattern 120a of FIG. 1 may be applied to the power rectifying device of FIG. 2D. In this case, the second gate electrode 135 may be in contact with a sidewall of the first gate electrode 125a.

Alternatively, the dielectric-spacer 180 and the gate dielectric patterns 172a and 120c of FIG. 2B or the dielectric-spacer 180a and the gate dielectric patterns 172a and 120b may be applied to the power rectifying device of FIG. 2D. In this case, a top end of the dielectric-spacer 180 or 180a between the first and second gate electrodes 125a and 135 may be lower than the top end of the second gate electrode 135.

FIG. 2E is a cross-sectional view illustrating a fifth modified example of a power rectifying device according to some embodiments of the inventive concept.

Referring to FIG. 2E, a second body region 140a may have a sidewall aligned with the sidewall of the first gate electrode 125. Thus, a width of the second body region 140a may be substantially equal to the width of the first body region 130. The second body region 140a is doped with dopants of the same conductivity type (i.e., the first conductivity type) as the first body region 130.

The second body region 140a according to the present modified example may be applied to the power rectifying devices illustrated in FIGS. 1 and 2A to 2D.

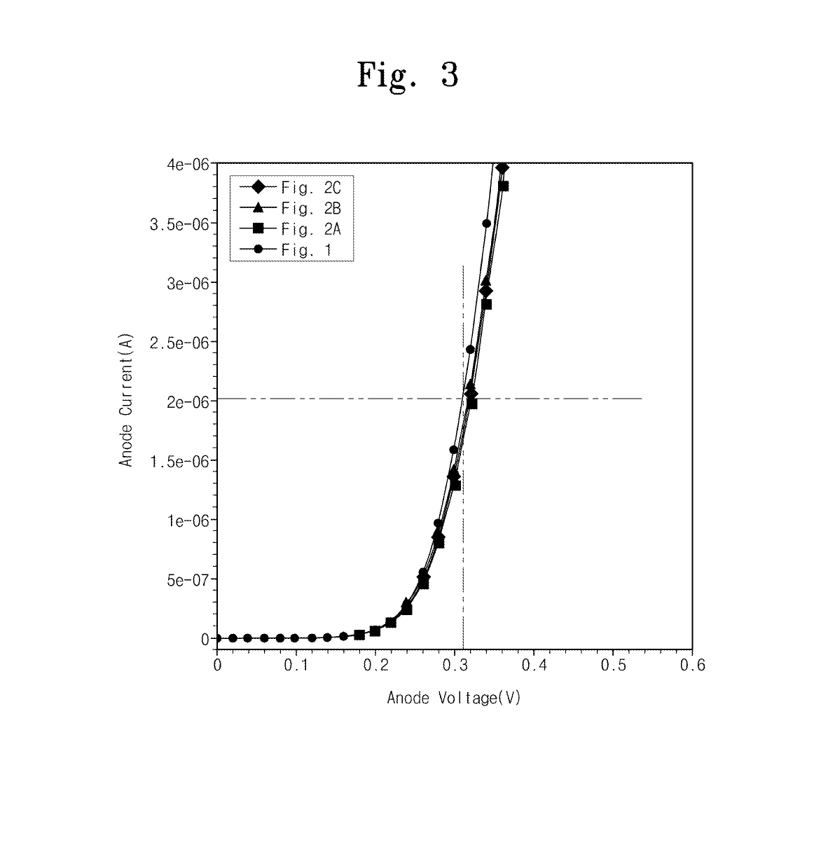

Next, the forward turn-on voltages of the power rectifying devices according to the present embodiment will be described with reference to a simulation graph of FIG. 3.

FIG. 3 is a simulation graph illustrating forward turn-on voltages of power rectifying devices according to some embodiments of the inventive concept. In the present simulation, the first conductivity type was the N-type and the second conductivity type was the P-type. The power rectifying devices of FIGS. 1, 2A, 2B, and 2C were applied to the present simulation.

As illustrated in FIG. 3, the forward turn-on voltages of the power rectifying devices of FIGS. 1 and 2A to 2C were about 0.3V at a standard (e.g., 1 μA per a gate length of 1 μm) of a general power device. Thus, the forward turn-on voltages of the power rectifying devices of FIGS. 1 and 2A to 2C were reduced. Dopant concentrations of the first body region 130 and the second body region 140 or 140a may be controlled to reduce or increase the forward turn-on voltages of the power rectifying devices.

Next, methods of manufacturing the power rectifying devices will be described with reference to drawings.

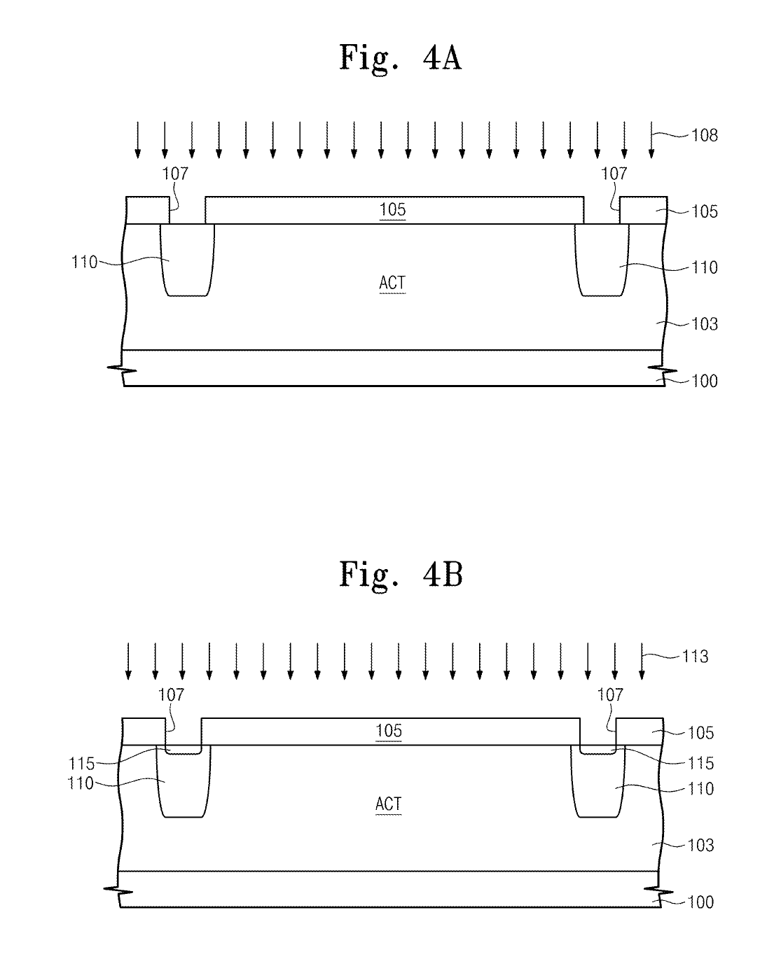

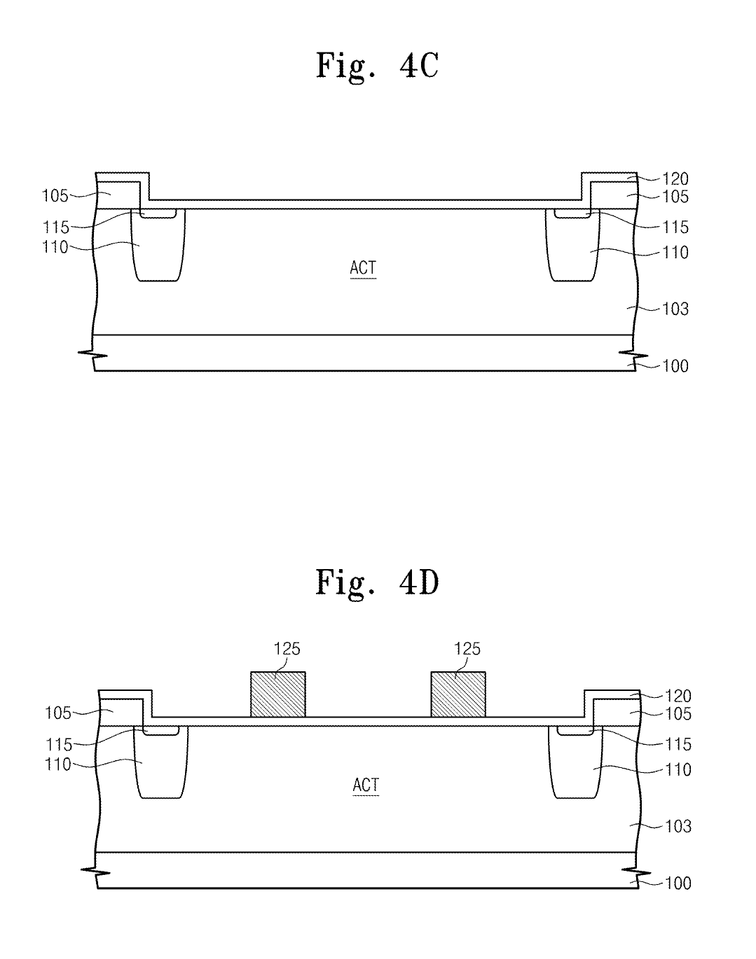

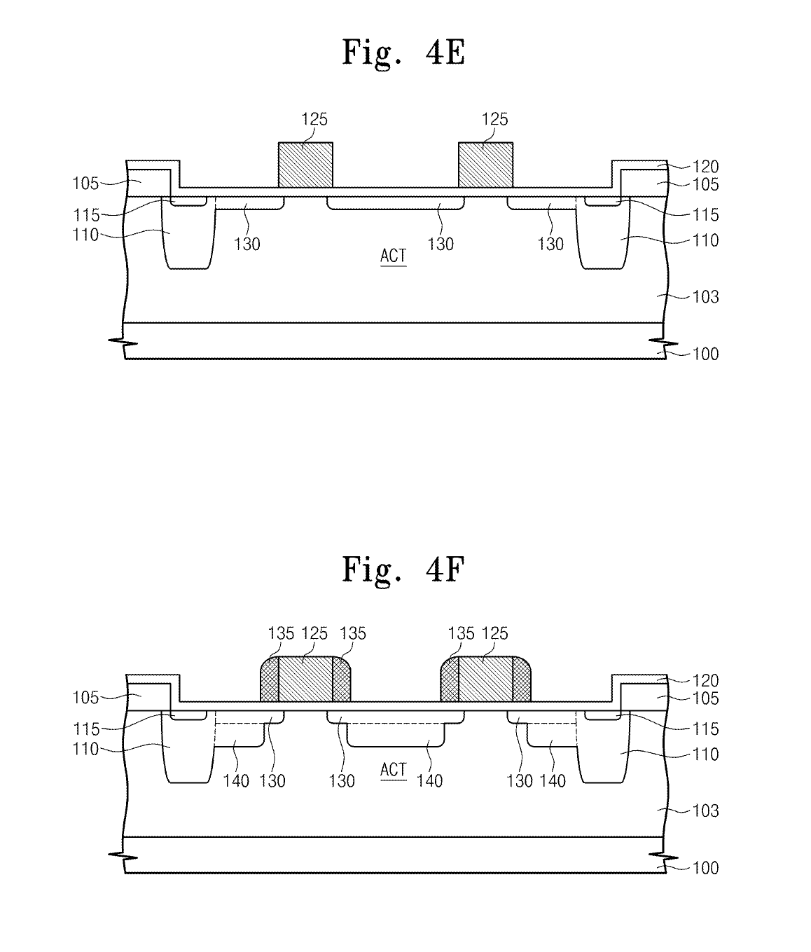

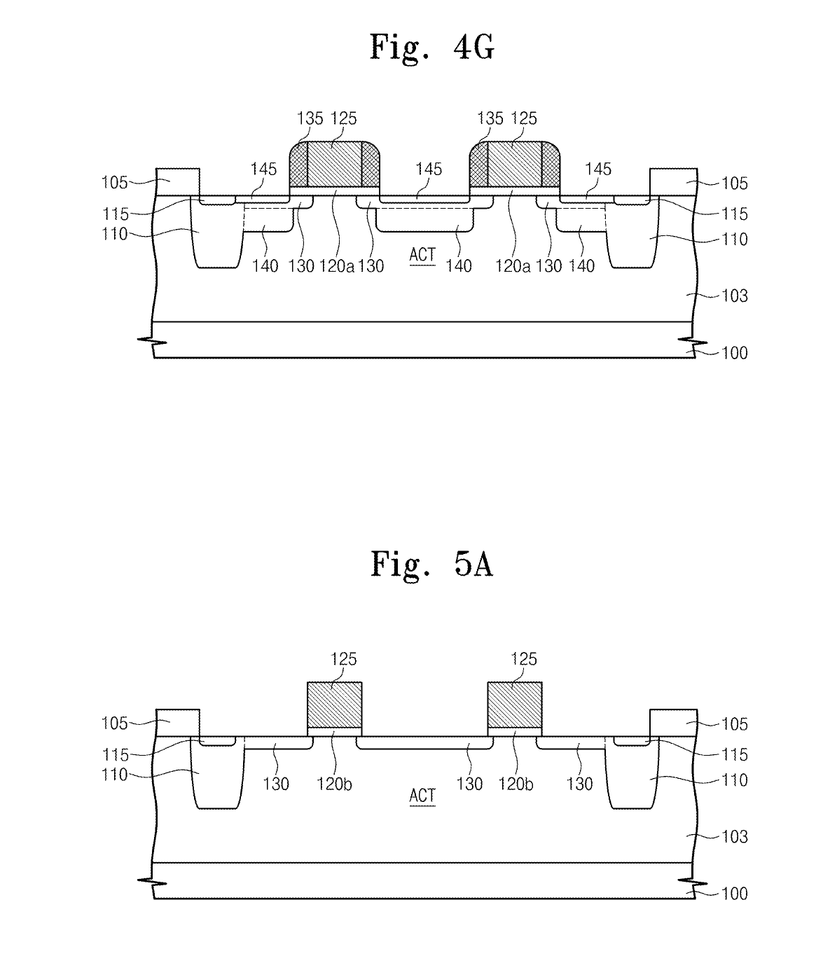

FIGS. 4A to 4G are cross-sectional views illustrating a method of manufacturing a power rectifying device according to some embodiments of the inventive concept.

Referring to FIG. 4A, an epitaxial layer 103 may be formed on a semiconductor substrate 100 of a first conductivity type. The epitaxial layer 103 may be formed by an epitaxial growth process. The epitaxial layer 103 is doped with dopants of the first conductivity type. The epitaxial layer 103 may be doped by an in-situ method or an ion implantation method.

A field insulating layer 105 may be formed on the epitaxial layer 103. The field insulating layer 105 may be patterned to form an opening 107 defining a guarding region 110 and a plug region (not shown). At this time, the field insulating layer 105 having the opening 107 may cover an active region ACT defined by the guarding region 110. The field insulating layer 105 may be formed of an oxide (e.g., silicon oxide). The field insulating layer 105 may have a thickness of about 100 nm to about 1000 nm.

Dopant ions 108 of a second conductivity type different from the first conductivity type may be implanted into the epitaxial layer 103 through the opening 107, and then a thermal treatment process may be performed. Thus, the guarding region 110 defining the active region ACT may be formed in the epitaxial layer 103. The guarding region 110 may have a depth of about 1 μm to about 10 μm. In another embodiment, when the power rectifying device has a operating voltage of about 40V or less, the formation of the guarding region 110 may be omitted. However, the inventive concept is not limited thereto.

Referring to FIG. 4B, dopant ions 113 of the second conductivity type may be implanted into the guarding region 110 to form a pickup region 115. A dopant concentration of the pickup region 115 may be higher than a dopant concentration of the guarding region 110. For example, a dose of the dopant ions 113 for the formation of the pickup region 115 may have a range of about 1×10¹⁴/cm² to about 1×10¹⁶/cm². After the dopant ions 113 are implanted, a thermal treatment process may be performed.

Referring to FIG. 4C, subsequently, the field insulating layer 105 disposed on the active region ACT may be removed to expose a top surface of the active region ACT. The field insulating layer 105 around the active region ACT may remain.

Subsequently, a gate dielectric layer 120 may be formed on the active region ACT. The gate dielectric layer 120 may be formed of an oxide (e.g., silicon oxide). The gate dielectric layer 120 may be formed by an oxidation process and/or a deposition process. The gate dielectric layer 120 may have a thickness of about 1 nm to about 100 nm.

Referring to FIG. 4D, a first gate layer may be deposited on the gate dielectric layer 120. The deposited first gate layer may be patterned to form a first gate electrode 125. If the first gate layer is a poly-silicon layer, the first gate layer may be doped with dopants of an N-type or a P-type. The first gate layer may be doped by an in-situ method, an ion implantation method, or a gas phase doping method (e.g., POCl₃ doping). Alternatively, the first gate layer may be in an undoped state. In this case, the first gate electrode 125 may be doped along with a second gate electrode or a source region in a subsequent process. As illustrated in FIG. 4D, a plurality of the first gate electrodes 125 may be formed on the active region ACT. The first gate layer may have a thickness of about 50 nm to about 1000 nm.

As illustrated in FIG. 4D, the gate dielectric layer disposed at both sides of the first gate electrode 125 may remain.

Referring to FIG. 4E, dopant ions of the second conductivity type may be implanted using the first gate electrode 125 as an mask into the active region ACT, thereby forming a first body region 130 at each side of the first gate electrode 125. After the dopant ions for the first body region 130 are implanted, a thermal treatment process may be performed to activate or diffuse the dopants in the first body region 130.

Referring to FIG. 4F, subsequently, a second gate layer may be conformally formed on the epitaxial layer 103, and then an etch-back process may be performed on the second gate layer to form a second gate electrode 135 on each sidewall of the first gate electrode 125. The second gate layer may be formed by a deposition process (e.g., a chemical vapor deposition (CVD) process or an atomic layer deposition (ALD) process). The second gate electrode 135 may have a spacer-shape disposed on the sidewall of the first gate electrode 125. If the second gate layer is formed of a poly-silicon layer, the second gate layer may be doped with dopants of an N-type or a P-type. The second gate layer may be doped by an in-situ method, an ion implantation method, or a gas phase doping method.

On the other hand, the gate dielectric layer 120 disposed at both sides of the first gate electrode 125 may be damaged during an etching process for the formation of the first gate electrode 125 and/or a formation process of the first body region 130. Thus, before the second gate layer is formed, a thermal treatment process may be performed for curing the damage of the gate dielectric layer 120 disposed at both sides of the first gate electrode 125. Additionally, after the second gate electrode 135 is formed, a thermal treatment process or an oxidation process may be performed to cure the damage of gate dielectric layer 120.

Subsequently, dopant ions may be implanted using the first and second gate electrodes 125 and 135 as masks into the active region ACT, thereby forming a second body region 140. The second body region 140 is deeper than the first body region 130. The dopant for the formation of the first body region 130 may be heavier than the dopant for the formation of the second body region 140. For example, if the second conductivity type is the P-type, the dopant for the formation of the first body region 130 may be BF₂, and the dopant for the formation of the second body region 140 may be boron (B).

Referring to FIG. 4G, dopant ions of the first conductivity type may be implanted using the first and second gate electrodes 125 and 135 as mask into the first body region 130, thereby forming a source region 145. After the dopant ions of the first conductivity type are implanted, a thermal treatment process may be performed to activate or diffuse the dopants in the source region 145.

The formation process of the source region 145 may be performed without an additional mask. In this case, a dose of the dopant ions for the formation of the source region 145 is smaller than a dose of the dopant ions for the formation of the pickup region 115. Thus, the pickup region 115 is not counter doped. Additionally, the dose of the dopant ions for the formation of the source region 145 is greater than the dose of the dopant ions of the formation of the first body region 130. Accordingly, the source region 145 formed in the body region 130 of the second conductivity type can have the first conductivity type.

Alternatively, the dopant ions for the formation of the source region 145 may be implanted using a mask pattern (not shown) covering the pickup region 115 and the first and second gate electrodes 125 and 135 as masks. In this case, the dose of the dopant ions for the formation of the source region 145 may be irrelative to the dose of the dopant ions for the formation of the pickup region 115.

The gate dielectric layer 120 disposed at both sides of the first and second gate electrodes 125 and 135 may be removed to expose the top surface of the active region ACT. At this time, a gate dielectric pattern 120a may be formed between the first gate electrode 125 and the active region ACT and between the second gate electrode 135 and the active region ACT. The second gate electrode 135 is disposed on the first body region 130.

After the source region 145 is formed, the gate dielectric layer 120 at both sides of the first and second gate electrodes 125 and 135 may be removed. Alternatively, after the gate dielectric layer 120 at both sides of the first and second gate electrodes 125 and 135 is removed, the source region 145 may be formed.

Next, the first electrode 150 of FIG. 1 may be formed. The first electrode 150 may be in contact with the pickup region 115, the source region 145, and the first and second gate electrodes 125 and 135. The second electrode 155 of FIG. 1 may be formed. In an embodiment, before the second electrode 155 is formed, a bottom surface of the semiconductor substrate 100 may be grinded to thin the semiconductor substrate 100. As a result, the power rectifying device of FIG. 1 may be realized.

In the method of manufacturing the power rectifying device described above, a channel length of the channel region under the second gate electrode 135 may be controlled by the thickness of the second gate layer. Since the second gate layer is formed by the deposition process, the thickness of the second gate layer may be accurately controlled with reproducibility. Thus, characteristics of the power rectifying device may be exactly controlled.

Modified examples of the manufacturing method according to the present embodiment will be described hereinafter. The modified examples may be similar to the manufacturing method mentioned above. Thus, differences between the aforementioned manufacturing method and the modified examples will be mainly described.

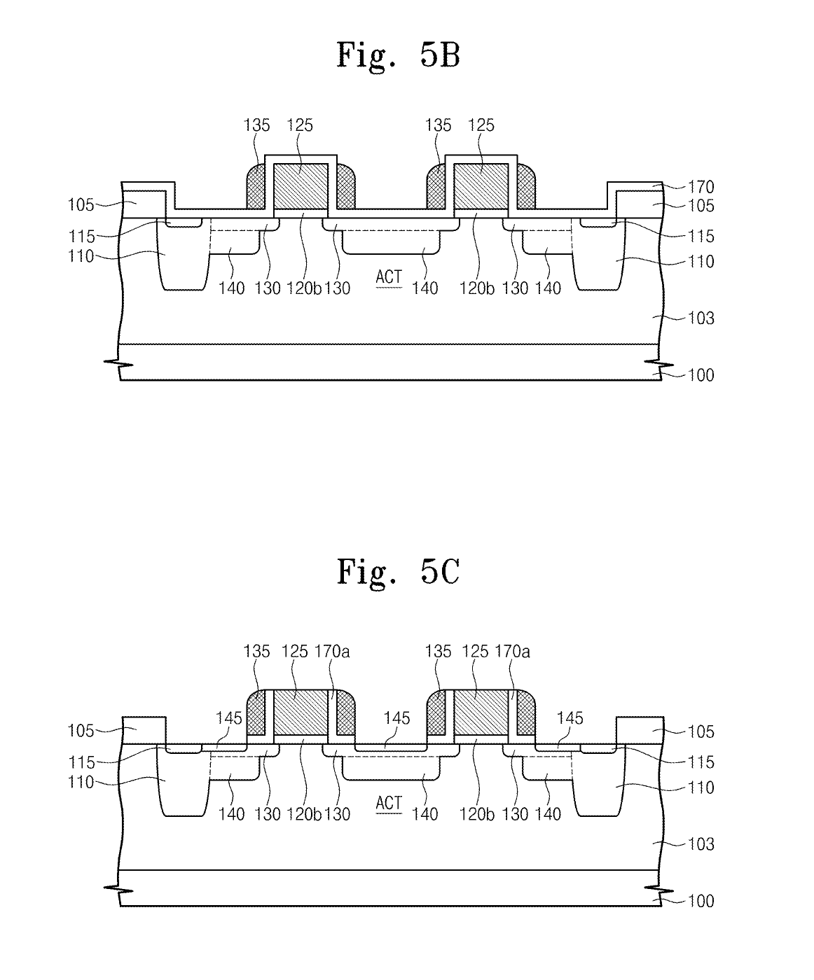

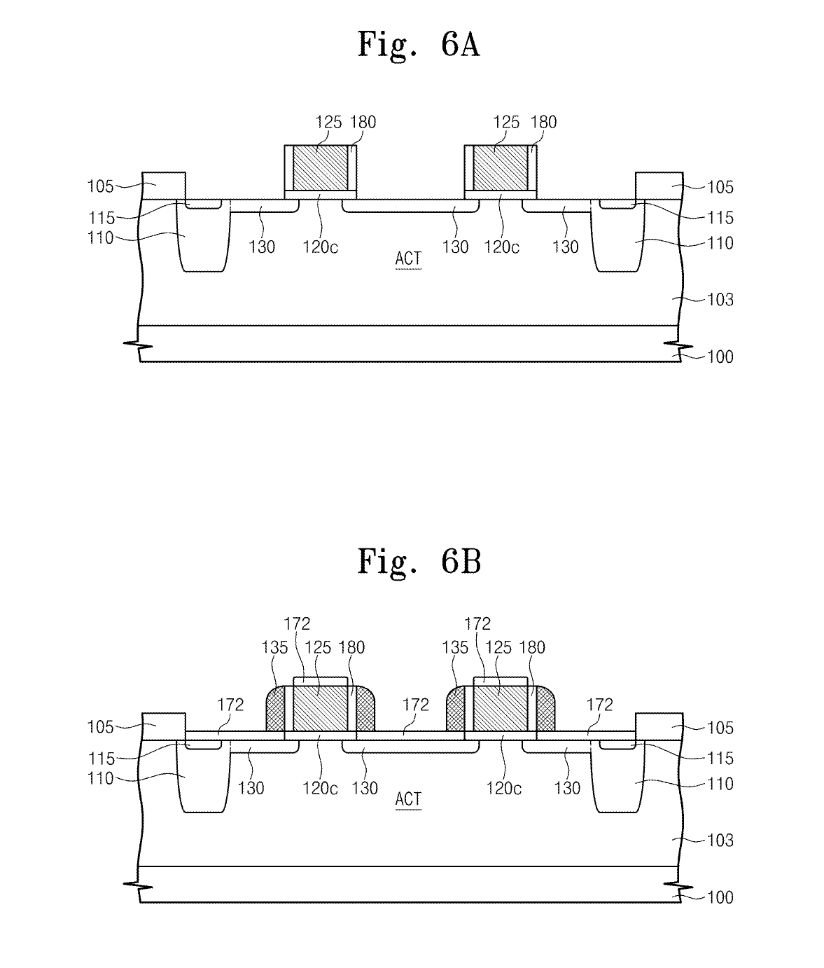

FIGS. 5A to 5C are cross-sectional views illustrating a first modified example of a method of manufacturing a power rectifying device according to some embodiments of the inventive concept. A manufacturing method according to the present modified example may include the processes described with reference to FIGS. 4A to 4D.

Referring to FIGS. 4D and 5A, the gate dielectric layer 120 at both sides of the first gate electrode 125 may be etched to form a first gate dielectric pattern 120b after the first gate electrode 125 is formed. Both sidewalls of the first gate dielectric pattern 120b may be aligned with both sidewalls of the first gate electrode 125, respectively. The first body region 130 may be formed in the active region ACT at each side of the first gate electrode 125. After the first body region 130 is formed, the first gate dielectric pattern 120b may be formed. Alternatively, after the first gate dielectric pattern 120b is formed, the first body region 130 may be formed.

Referring to FIG. 5B, a second gate dielectric layer 170 may be conformally formed on the epitaxial layer 130. The second gate dielectric layer 170 may be formed by an oxidation process and/or a deposition process. The second gate dielectric layer 170 may have a thickness of about 1 nm to about 100 nm. If the second gate dielectric layer 170 is formed by the oxidation process and the deposition process, an oxide layer having a thickness of about 1 nm to about 10 nm may be formed by the oxidation process and then a nitride layer (e.g., a silicon nitride layer) having a thickness of about 1 nm to about 10 nm may be formed by the deposition process. In other words, the second gate dielectric layer 170 may include the oxide layer and the nitride layer.

Subsequently, the second gate layer may be formed and then the etch-back process may be performed on the second gate layer to form the second gate electrode 135.

According to the present modified example, after the damaged gate dielectric layer 120 at both sides of the first gate electrode 125 is removed, the second gate dielectric layer 170 may be formed. Thus, the second gate dielectric layer 170 having excellent characteristics may be formed under the second gate electrode 135.

Next, the second body region 140 may be formed, and the source region 145 may be formed. The second gate dielectric layer 170 may be etched to expose the top surface of the first gate electrode 125 and the active region ACT. After the second body region 140 and the source region 145 are formed, the second gate dielectric layer 170 may be etched to expose the top surface of the first gate electrode 125 and the active region ACT. Alternatively, before the source region 145 is formed, the second gate dielectric layer 170 may be etched. Subsequently, the first and second electrodes 150 and 155 of FIG. 2A may be formed. As a result, the power rectifying device of FIG. 2A may be realized.

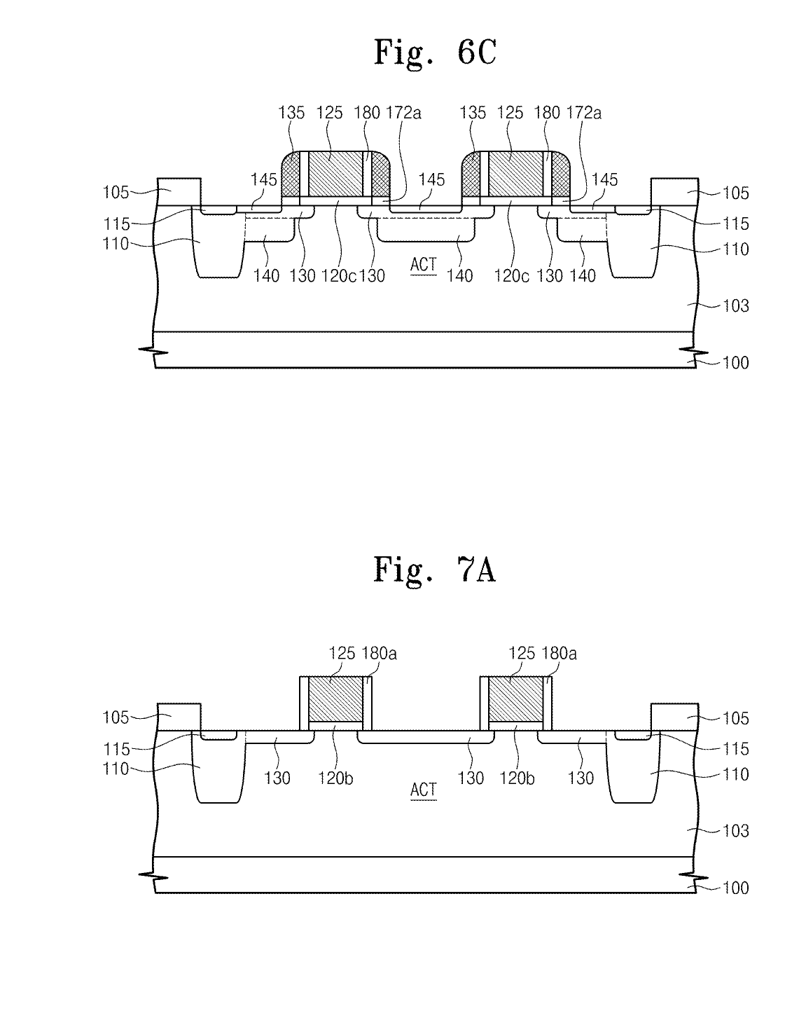

FIGS. 6A to 6C are cross-sectional views illustrating a second modified example of a method of manufacturing a power rectifying device according to some embodiments of the inventive concept. A manufacturing method according to the present modified example may include the processes described with reference to FIGS. 4A to 4D.

Referring to FIGS. 4D and 6A, a dielectric-spacer layer may be conformally formed on the substrate having the first gate electrode 125, and then an etch-back process may be performed on the dielectric-spacer layer to form a dielectric-spacer 180 on each sidewall of the first gate electrode 125. Subsequently, the gate dielectric layer 120 may be etched to form a first gate dielectric pattern 120c. The dielectric-spacer layer may be formed of a different dielectric material from the first gate dielectric pattern 120c. For example, the dielectric-spacer layer may be formed of a nitride layer (e.g., a silicon nitride layer). The dielectric-spacer layer may have a thickness of about 1 nm to about 100 nm.

The first body region 130 may be formed before the formation of the dielectric-spacer layer or after the formation of the dielectric-spacer 180.

Referring to FIG. 6B, a second gate dielectric layer 172 may be formed. The second gate dielectric layer 172 may be formed by an oxidation process and/or a deposition process. FIG. 6B illustrates the second gate dielectric layer 172 formed by the oxidation process. During the oxidation process, both sidewalls of the first gate electrode 125 may be protected by the dielectric-spacers 180. Thus, the sidewalls of the first gate electrode 125 may not be oxidized. Subsequently, the second gate layer may be conformally formed and then the etch-back process may be performed on the second gate layer to form the second gate electrode 135. If the second gate dielectric layer 172 is formed by the deposition process, the second gate dielectric layer 172 may be formed between the second gate electrode 135 and the dielectric-spacer 180.

Referring to FIG. 6C, the second body region 140 may be formed and the source region 145 may be formed. The second gate dielectric layer 172 may be etched to expose the top surface of the first gate electrode 125 and the active region ACT. At this time, a second gate dielectric pattern 172a may be formed between the second gate electrode 135 and the active region ACT (i.e., the first body region 130). If the second gate dielectric layer 172 is also formed between the second gate electrode 135 and the dielectric-spacer 180, the second gate dielectric pattern 172a may extend between the second gate electrode 135 and the dielectric-spacer 180. Subsequently, the first and second electrodes 150 and 155 of FIG. 2B may be formed to realize the power rectifying device of FIG. 2B.

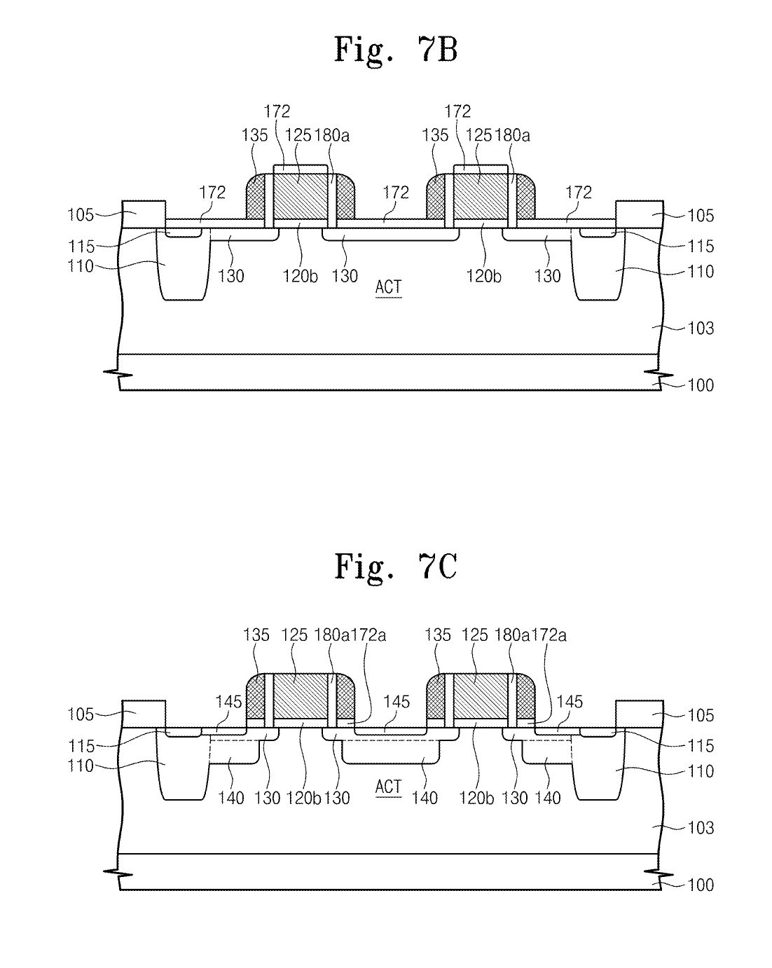

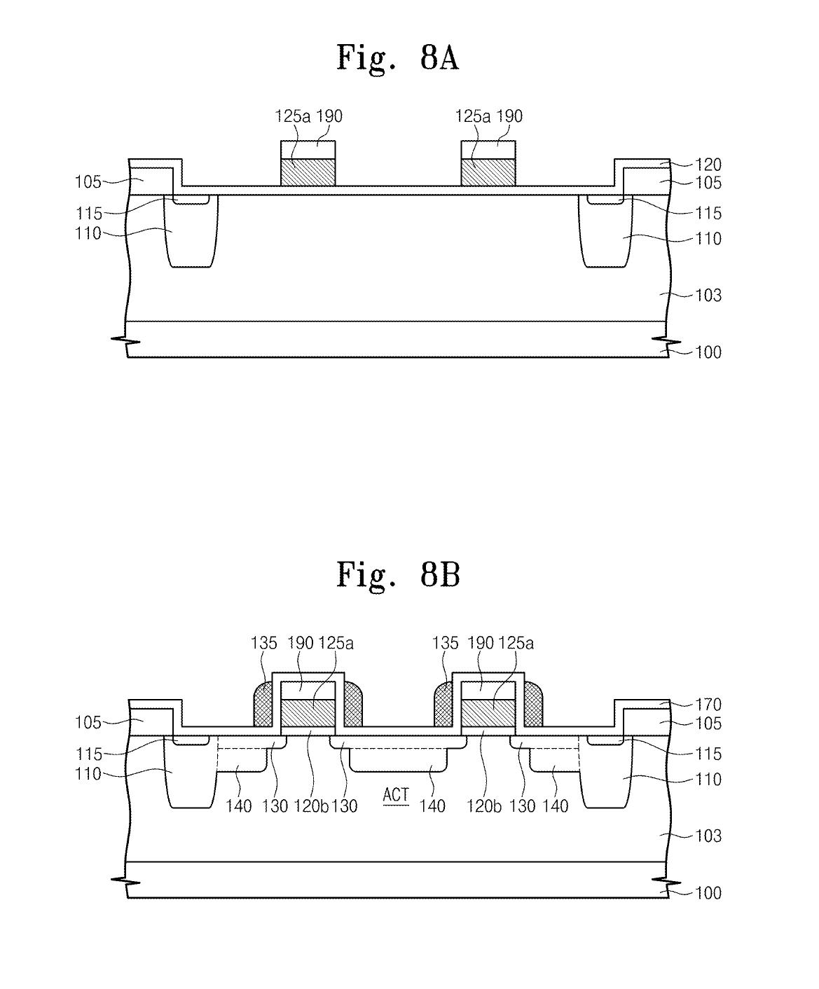

FIGS. 7A to 7C are cross-sectional views illustrating a third modified example of a method of manufacturing a power rectifying device according to some embodiments of the inventive concept. A manufacturing method according to the present modified example may include the processes described with reference to FIGS. 4A to 4D and 5A.

Referring to FIGS. 5A and 7A, the dielectric-spacer layer may be conformally formed on the substrate having the first gate electrode 125 and the first gate dielectric pattern 120b, and an etch-back process may be performed on the dielectric-spacer layer to form a dielectric-spacer 180a on each sidewall of the first gate electrode 125. The dielectric-spacer 180a also covers each sidewall of the first gate dielectric pattern 120b.

Referring to FIG. 7B, the second gate dielectric layer 172 may be formed, and the second gate electrode 135.

Referring to FIG. 7C, the second body region 140 may be formed and the source region 145 may be formed. The second gate dielectric layer 172 may be etched to expose the top surface of the first gate electrode 125 and the active region ACT. At this time, the second gate dielectric pattern 172a may be formed. Subsequently, the first and second electrodes 150 and 155 of FIG. 2C may be formed to realize the power rectifying device of FIG. 2C.

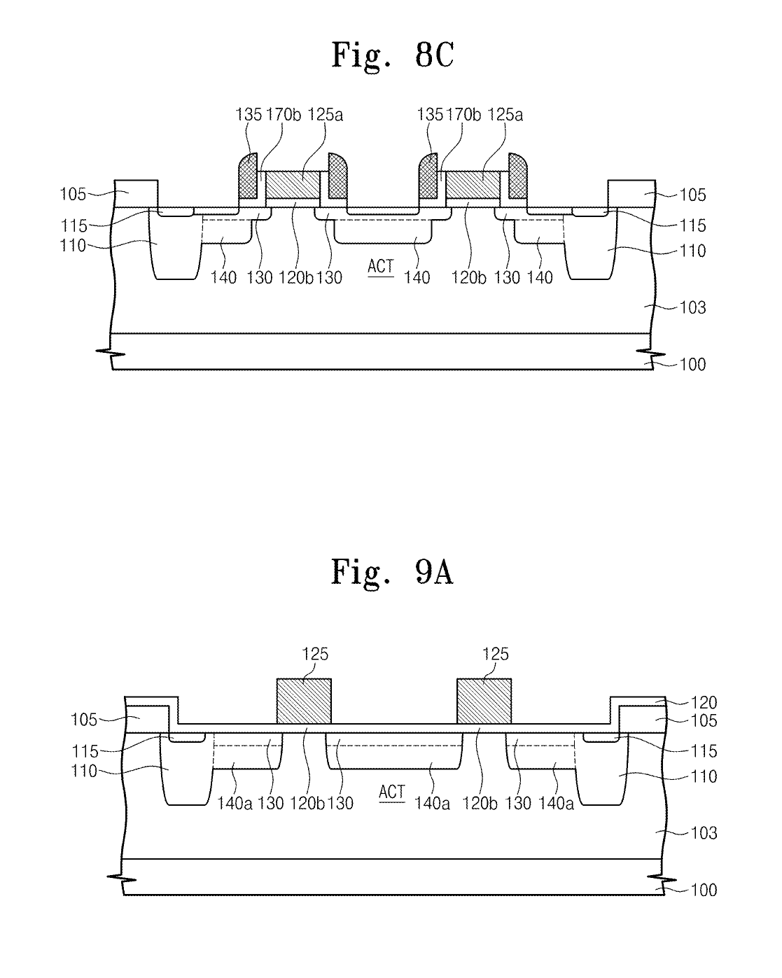

FIGS. 8A to 8C are cross-sectional views illustrating a fourth modified example of a method of manufacturing a power rectifying device according to some embodiments of the inventive concept. A manufacturing method according to the present modified example may include the processes described with reference to FIGS. 4A to 4C.

Referring to FIGS. 4C and 8A, a first gate layer and a sacrificial layer may be sequentially formed on the gate dielectric layer 120. The sacrificial layer and the first gate layer may be successively patterned to form a first gate electrode 125a and a sacrificial pattern 190 which are sequentially stacked. The first gate electrode 125a may be formed of the same material as the first gate electrode 125 of FIG. 4D. The first gate electrode 125a may have a thickness of about 10 nm to about 200 nm, and the sacrificial pattern 190 may have a thickness of about 50 nm to about 1000 nm. The sacrificial pattern 190 may be formed of an oxide (e.g., silicon oxide).

Referring to FIG. 8B, the first body region 130 may be formed. The gate dielectric layer 120 at both sides of the first gate electrode 125a may be removed to form the first gate dielectric pattern 120c. Subsequently, the second gate dielectric layer 170 may be conformally formed and then the second gate electrode 135 may be formed. Next, the second body region 140 may be formed. Alternatively, the dielectric-spacer 180 and the second gate dielectric layer 172 of FIGS. 6A and 6B may be applied to FIG. 8B, or the dielectric-spacer 180a and the second gate dielectric layer 172 of FIGS. 7A and 7B may be applied to FIG. 8B.

Referring to FIG. 8C, the second body region 140 may be formed and the source region 145 may be formed. The second gate dielectric layer 170 and the sacrificial pattern 190 may be etched to expose a top surface of the first gate electrode 125a and the active region ACT. At this time, a second gate dielectric pattern 170b may be formed between the second gate electrode 135 and the first body region 130 and between the second gate electrode 135 and the first gate electrode 125a. A top end of the second gate dielectric pattern 170b between the first and second gate electrodes 125a and 135 may be lower than a top end of the second gate electrode 135. Subsequently, the first and second electrodes 150 and 155 of FIG. 2D may be formed to realize the power rectifying device of FIG. 2D.

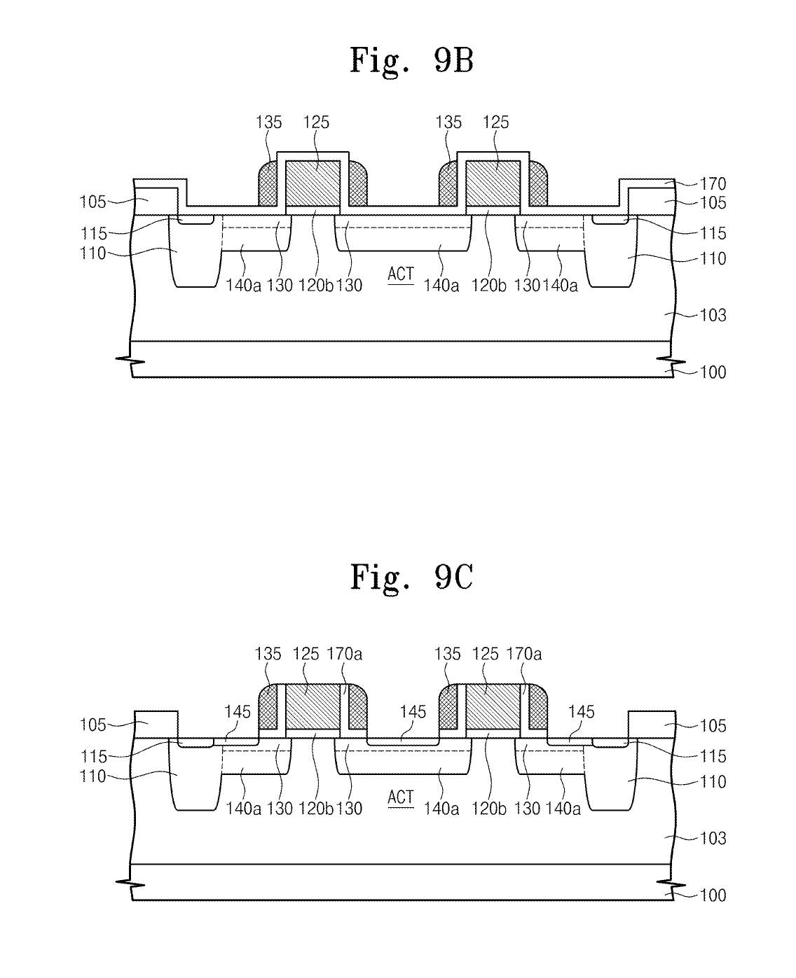

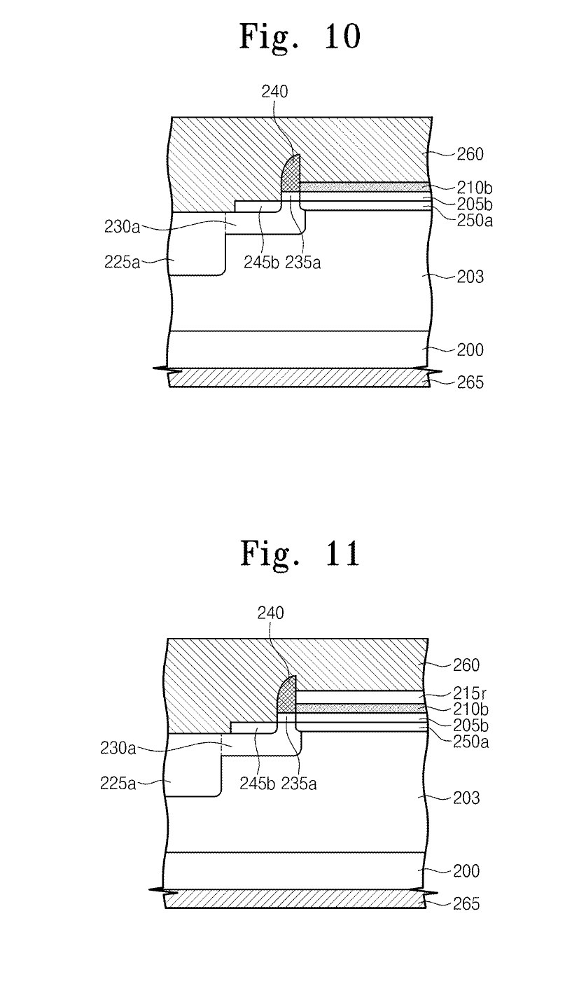

FIGS. 9A to 9C are cross-sectional views illustrating a fifth modified example of a method of manufacturing a power rectifying device according to some embodiments of the inventive concept. A manufacturing method according to the present modified example may include the processes described with reference to FIGS. 4A to 4E.

Referring to FIGS. 4E and 9A, after the formation of the first body region 130, dopant ions of the second conductivity type may be implanted using the first gate electrode 125 as a mask to form a second body region 140a. All of the first and second body regions 130 and 140a may be formed using the first gate electrode 125 as the mask, such that widths of the first and second body regions 130 and 140a may be substantially equal to each other.

Referring to FIG. 9B, subsequently, the gate dielectric layer 120 at both sides of the first gate electrode 125 may be removed to form the first gate dielectric pattern 120b. The second gate dielectric layer 170 may be formed and then the second gate electrode 135 may be formed.

Referring to FIG. 9C, the source region 145 may be formed. The second gate dielectric layer 170 may be etched to expose the top surface of the first gate electrode 125 and the active region ACT. Subsequently, the first and second electrodes 150 and 155 of FIG. 2E may be formed to realize the power rectifying device of FIG. 2E.

The modified examples described above may be combined in various forms under a non-contradictable condition.

### Second Embodiment

FIG. 10 is a cross-sectional view illustrating a power rectifying device according to other embodiments of the inventive concept.

Referring to FIG. 10, a substrate doped with dopants of a first conductivity type may be provided. In an embodiment, the substrate of the first conductivity type may include a semiconductor substrate 200 and an epitaxial layer 203 on a top surface of the semiconductor substrate 200. The semiconductor substrate 200 may be a silicon substrate. The epitaxial layer 203 may be a silicon layer formed by an epitaxial growth process. The semiconductor substrate 20 is doped with dopants of the first conductivity type, and the epitaxial layer 103 is also doped with dopants of the first conductivity type. A dopant concentration of the semiconductor substrate 200 may be higher than a dopant concentration of the epitaxial layer 203.

A guarding region 225a and a plug region (not shown) may be disposed in the epitaxial layer 203. The guarding region 225a may define an active region. The guarding region 225a is doped with dopants of a second conductivity type different from the first conductivity type. One of the first and second conductivity types is an N-type and the other of the first and second conductivity types is a P-type.

An etch stop pattern 210b may be disposed on the active region. The etch stop pattern 210b has a flat top surface. For example, the etch stop pattern 210b may be formed of a nitride (e.g., silicon nitride).

A body region 230a may be disposed in the active region between the etch stop pattern 210b and the guarding region 225a. The body region 230a is doped with dopants of the same conductivity type (i.e., the second conductivity type) as the guarding region 225a. A depth of the body region 230a is less than that of the guarding region 225a. The etch stop pattern 210b has a sidewall adjacent to the body region 230a.

A buffer dielectric pattern 205b may be disposed between the etch stop pattern 210b and the active region. The buffer dielectric pattern 205b may relax a stress between the etch stop pattern 210b and the active region. The buffer dielectric pattern 205b has a sidewall aligned with the sidewall of the etch stop pattern 210b, which is adjacent to the body region 230a. For example, the buffer dielectric pattern 205b may be formed of an oxide (e.g., silicon oxide).

A gate electrode 240 is disposed on the sidewall of the etch stop pattern 210b and on the body region 230a. A gate dielectric pattern 235a is disposed between the gate electrode 240 and the body region 230a. The gate electrode 240 has a first sidewall adjacent to the sidewall of the etch stop pattern 210b and a second sidewall of the first sidewall. The first sidewall of the gate electrode 240 may be substantially vertically flat, and the second sidewall of the gate electrode 240 may include a rounded portion. A top end of the gate electrode 240 may be higher than the top surface of the etch stop pattern 210b.

The gate electrode 240 may be in contact with the sidewall of the etch stop pattern 210b, and the gate dielectric pattern 235a may be confinedly disposed between the gate electrode 240 and the body region 230a. Alternatively, the gate dielectric pattern 235a may extend between the gate electrode 240 and the etch stop pattern 210b.

The gate electrode 240 may be formed of the same material as the second gate electrode 135 of FIG. 1. The gate dielectric pattern 235a may be formed of the same material as the gate dielectric pattern 120a of FIG. 1.

A source region 245b is formed in the body region 230a at a side of the gate electrode 240. The gate electrode 240 is disposed on the body region 230a between the source region 245b and the etch stop pattern 210b. The source region 245b is doped with dopants of the first conductivity type. A channel region is defined in the body region 230a under the gate electrode 240. The active region (i.e., the epitaxial layer 203), which is disposed under the etch stop pattern 210b and beside the body region 230a, corresponds to a drain region. The drain region is electrically connected to the semiconductor substrate 200 through the epitaxial layer 203.

In an embodiment, a surface doped region 250a may be formed beneath a surface of the active region (i.e., a surface of the epitaxial layer 203) under the etch stop pattern 210b. The surface doped region 250a is doped with dopants of the same conductivity type as the epitaxial layer 203. In other words, the surface doped region 250a is doped with dopants of the first conductivity type. A dopant concentration of the surface doped region 250a is higher than a dopant concentration of the epitaxial layer 203. Thus, the surface doped region 250a may have a resistance value lower than that of the epitaxial layer 203. The surface doped region 250a is included in the drain region. Electrical characteristics of the power rectifying device may be controlled by the surface doped region 250a.

In an embodiment, a top surface of the guarding region 225a at a side of the source region 245b may be recessed to be lower than a top surface of the source region 245b. In other words, a top surface of the epitaxial layer 203 in which the guarding region 225a is formed may be recessed to be lower than a top surface of the epitaxial layer 203 in which the source region 245b is formed. Electrical characteristics of the power rectifying device may be controlled according to a height of the top surface of the guarding region 225a.

The gate electrode 240, the source region 245b, and the body region 230a are electrically connected in common to a first terminal, and the epitaxial layer 203 under the etch stop pattern 210b, for example, the drain region is electrically connected to a second terminal. In more detail, a first electrode 260 may be disposed on the substrate (i.e., the epitaxial layer 203). The first electrode 260 is electrically connected to the gate electrode 240, the source region 245b, and the body region 230a. For example, the first electrode 260 may be in contact with the gate electrode 240, the source region 245b, and the guarding region 225a as illustrated in FIG. 10. Additionally, the first electrode 260 may also be in contact with the body region 230a between the source region 245b and the guarding region 225a. The first electrode 260 may be in contact with the second sidewall of the gate electrode 240. Additionally, the first electrode 260 may also be in contact with the first sidewall of the gate electrode 240 which is higher than the top surface of the etch stop pattern 210b.

A second electrode 265 is disposed on a bottom surface of the semiconductor substrate 200. The second electrode 265 is electrically connected to the drain region beside the body region 230a through the semiconductor substrate 200 and the epitaxial layer 203. For example, the first electrode 260 and the second electrode 265 may correspond to the first terminal and the second terminal, respectively. The first and the second electrodes 260 and 265 may be formed of the same materials as the first and second electrodes o150 and 155 of FIG. 1, respectively.

FIG. 11 is a cross-sectional view illustrating a modified example of a power rectifying device according to other embodiments of the inventive concept.

Referring to FIG. 11, according to the present modified example, a residual support pattern 215r may be disposed between the top surface of the etch stop pattern 210b and the first electrode 260. The residual support pattern 215r may be formed of a dielectric material having an etch selectivity with respect to the etch stop pattern 210b. For example, the residual support pattern 215r may include an oxide (e.g., silicon oxide). The residual support pattern 215r may have a sidewall aligned with the sidewall of the etch stop pattern 210b which is adjacent to the gate electrode 240. A top surface of the residual support pattern 215r may be flat. A contact area of the first electrode 260 and the gate electrode 240 may be varied according to a thickness of the residual support pattern 215r. Thus, the residual support pattern 215r may control the electrical characteristics of the power rectifying device.

A method of manufacturing the power rectifying devices according to the present embodiment will be described hereinafter.

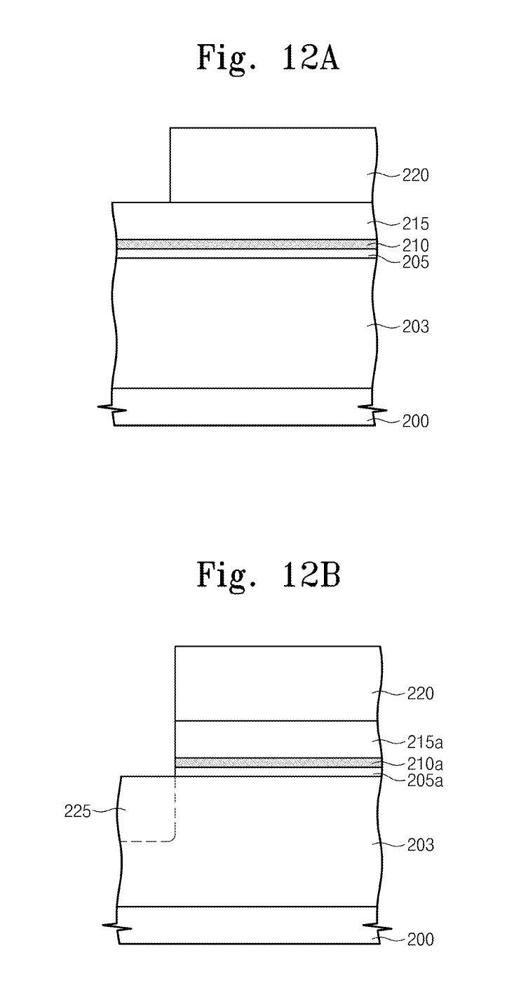

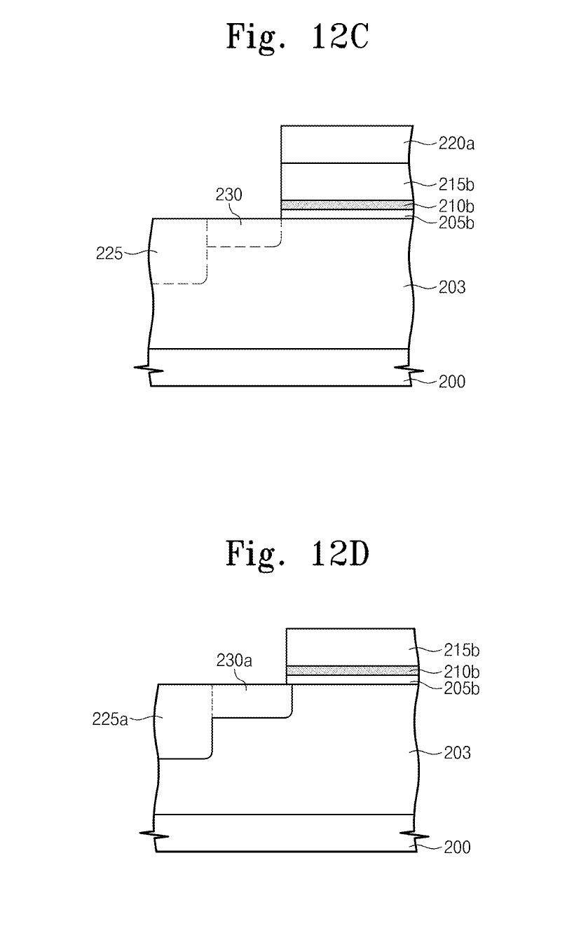

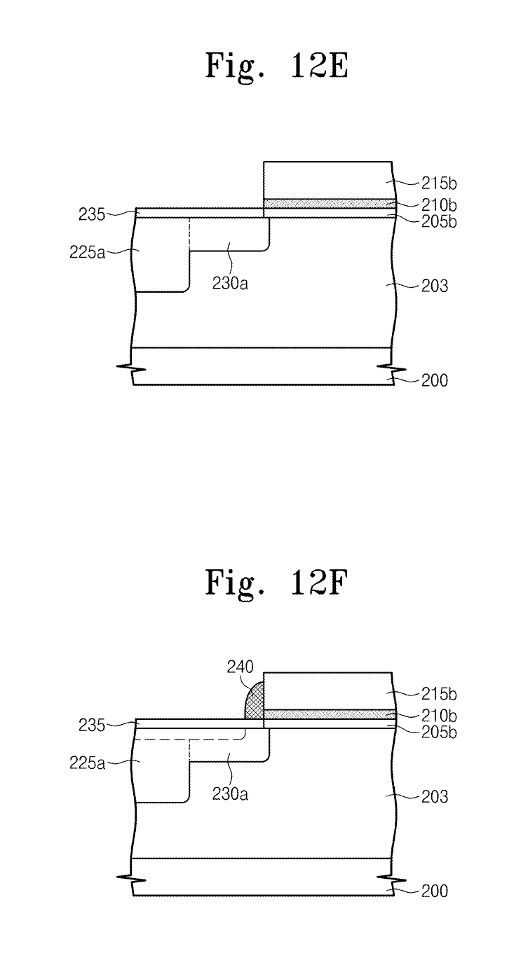

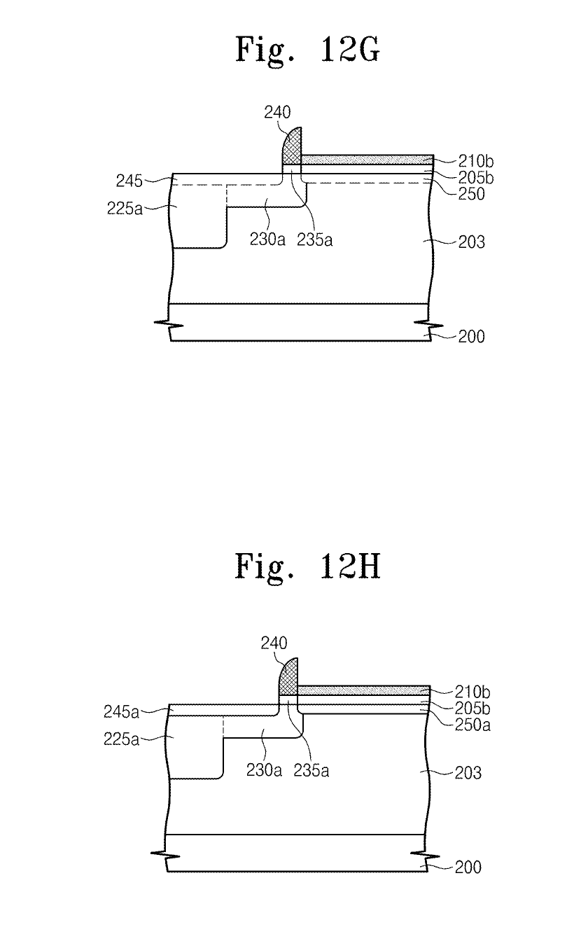

FIGS. 12A to 12H are cross-sectional views illustrating a method of manufacturing a power rectifying device according to other embodiments of the inventive concept.

Referring to FIG. 12A, a substrate doped with dopants of a first conductivity type is prepared. The substrate may include a semiconductor substrate 200 and an epitaxial layer 203 disposed on the semiconductor substrate 200. The semiconductor substrate 200 and the epitaxial layer 203 are doped with dopants of the first conductivity type. A dopant concentration of the semiconductor substrate 200 may be greater than a dopant concentration of the epitaxial layer 203.

A buffer dielectric layer 205, an etch stop layer 210, and a support layer 215 may be sequentially formed on the epitaxial layer 203. The support layer 215 may be formed of a dielectric material having an etch selectivity with respect to the etch stop layer 210. For example, the support layer 215 may be formed of an oxide (e.g., silicon oxide), and the etch stop layer 210 may be formed of a nitride (e.g., silicon nitride). The buffer dielectric layer 205 may be formed of a dielectric material (e.g., an oxide) relaxing a stress between the etch stop layer 210 and the epitaxial layer 203.

A mask pattern 220 defining a guarding region may be formed on the support layer 215. The mask pattern 220 may be formed of a photoresist.

Referring to FIG. 12B, the support layer 215, the etch stop layer 210, and the buffer dielectric layer 205 may be successively etched using the mask pattern 220 as a mask, thereby forming a preliminary support pattern 215a, a preliminary etch stop pattern 210a, and a preliminary buffer dielectric pattern 205a. Thereafter, dopant ions of a second conductivity type may be implanted into the epitaxial layer 203 to form a guarding implantation region 225. In an embodiment, the preliminary buffer dielectric pattern 205a may be formed after the guarding implantation region 225 is formed. In more detail, after the preliminary support pattern 215a and the preliminary etch stop pattern 210a are formed, the guarding implantation region 225 may be formed. Subsequently, the buffer dielectric layer 205 may be etched to form the preliminary buffer dielectric pattern 210a.

Referring to FIG. 12C, the mask pattern 220 may be partially etched to expose a portion of a top surface of the preliminary support pattern 215a. Subsequently, the preliminary support pattern 215a, the preliminary etch stop pattern 210a, and the preliminary buffer dielectric pattern 205a may be etched using the etched mask pattern 220a to form a buffer dielectric pattern 205b, a etch stop pattern 210b, and a support pattern 215 which are sequentially stacked. Thereafter, dopant ions of the second conductivity type may be implanted using the etched mask pattern 220a as an ion implantation mask into the epitaxial layer 203 between the guarding implantation region 225 and the support pattern 215b, thereby forming a body implantation region 230.

Referring to FIG. 12D, the etched mask pattern 220a may be removed and then a thermal treatment process may be performed to form a guarding region 225a and a body region 230a. Due to the thermal treatment process, the dopants in the guarding implantation region 225 may be activated and/or diffused to form the guarding region 225a, and the dopants in the body implantation region 230 may be activated and/or diffused to form the body region 230a.

Referring to FIG. 12E, a gate dielectric layer 235 may be formed on the guarding region 225a and the body region 230a. The gate dielectric layer 235 may be formed by an oxidation process and/or a deposition process.

Referring to FIG. 12F, a gate layer may be conformally formed on the substrate having the gate dielectric layer 235 and the support pattern 215b, and then an etch-back process may be performed on the gate layer to form a gate electrode 240 on a sidewall of the support pattern 215b. The gate electrode 240 is formed of a conductive material. For example, the gate electrode 240 may be formed of a doped poly-silicon. However, the inventive concept is not limited thereto. The gate electrode 240 may be formed of at least one of other conductive materials.

Dopant ions of the first conductivity type may be implanted using the gate electrode 240 and the support pattern 215b as masks into the body region 230a, thereby forming a source implantation region 245. The source implantation region 245 may also be formed in an upper portion of the guarding region 225a.

Referring to FIG. 12G, subsequently, the support pattern 215b may be removed to expose the etch stop pattern 210b. At this time, the gate dielectric layer 235 disposed on the source implantation region 245 and beside the gate electrode 240 may be removed to form a gate dielectric pattern 235a between the gate electrode 240 and the body region 230a.

Thereafter, dopant ions of the first conductivity type may be implanted to form a surface implantation region 250 in the epitaxial layer 203 under the etch stop pattern 210b. The surface implantation region 250 has the same conductivity type as the epitaxial layer 203.

Meanwhile, the support pattern 215b may be partially etched to form the residual support pattern 215r of FIG. 11 on the etched stop pattern 210b.

Referring to FIG. 12H, a second thermal treatment process may be performed on the substrate having the source implantation region 245 and the surface implantation region 250, thereby forming a source region 245a and a surface doped region 250a. Due to the second thermal treatment process, dopants in the source and surface implantation regions 245 and 250 may be activated and/or diffused to form the source region 245a and the surface doped region 250a.

Referring to FIG. 10, a portion of the source region 245a, which is disposed on the guarding region 225a, may be etched to expose the guarding region 225a. In other words, the epitaxial layer 203 in which the source region 245a on the guarding region 225a is formed may be etched to expose the guarding region 225a. Thus, a source region 245b may be formed in the body region 230a at a side of the gate electrode 240. Subsequently, first and second electrodes 260 and 265 may be formed to realize the power rectifying device of FIG. 10.

Meanwhile, as described above, if the residual support pattern 215r remains on the etch stop pattern 210b, the power rectifying device of FIG. 11 may be realized.

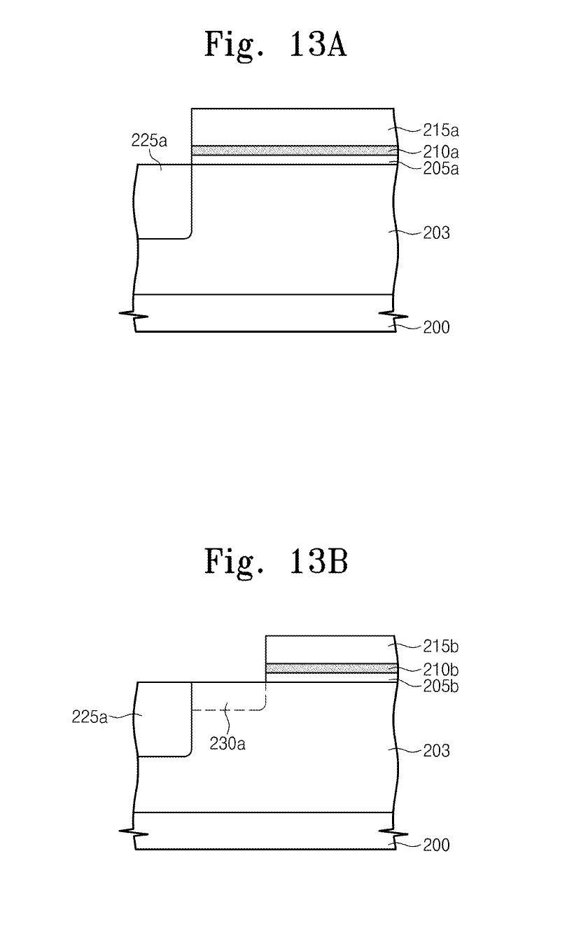

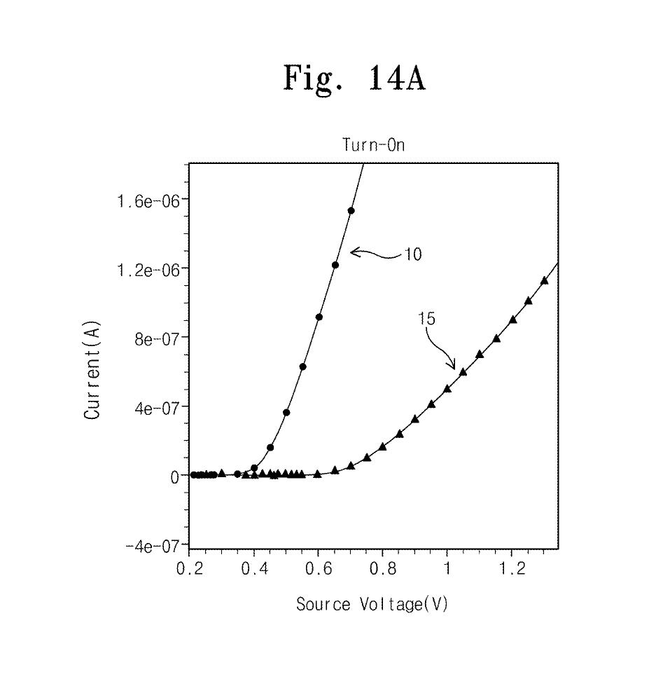

The guarding region 225a and the body region 230a may be formed by another method. This will be described with reference to FIGS. 13A and 13B.

FIGS. 13A and 13B are cross-sectional views illustrating a modified example of a method of manufacturing a power rectifying device according to other embodiments of the inventive concept. A manufacturing method according to the present modified example may include the processes described with reference to FIGS. 12A and 12B.

Referring to FIGS. 12B and 13A, the mask pattern 220 may be removed after the formation of the guarding implantation region 225. A thermal treatment process may be performed on the guarding implantation region 225 to form the guarding region 225a.

Referring to FIG. 13B, the preliminary support pattern 215a, the preliminary etch stop pattern 210a, and the preliminary buffer dielectric pattern 205a may be partially etched to form a buffer dielectric pattern 205b, a etch stop pattern 210b, and a support pattern 215b which are sequentially stacked. The support pattern 215b of FIG. 13B may be thinner than the support pattern 215b of FIG. 12D. Thereafter, dopant ions of the second conductivity type may be implanted into the epitaxial layer 203 between the support pattern 215b and guarding region 225a, thereby forming a body implantation region 230. Subsequently, a thermal treatment process may be performed to the body region 230a of FIG. 12D. Next, the processes described with reference to FIGS. 12E to 12H and 10 may be performed.

Simulations were performed for verifying characteristics of the power rectifying devices according to the present embodiment.

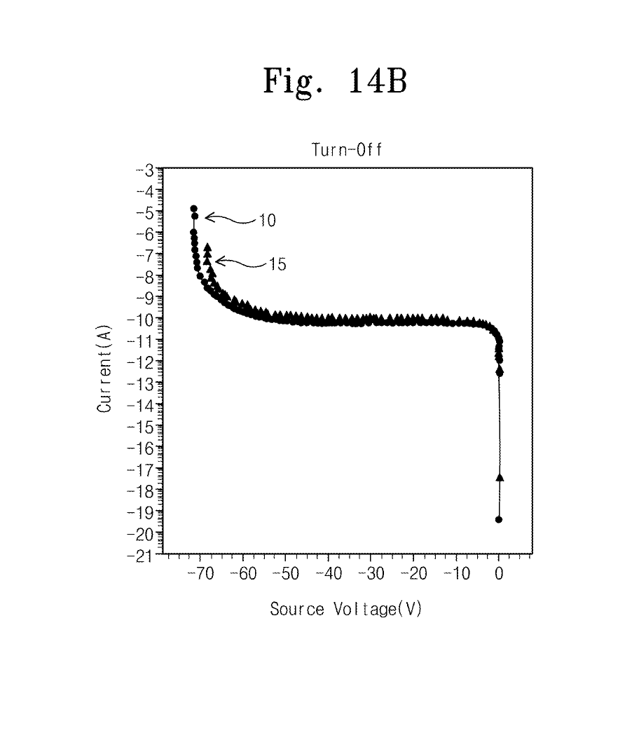

FIGS. 14A and 14B are graphs illustrating a turn-on characteristic and a turn-off characteristic related to a support pattern in a power rectifying device according to other embodiments of the inventive concept, respectively.

Referring to FIGS. 14A and 14B, a reference numeral ‘10’ shows a turn-on characteristic and a turn-off characteristic of the power rectifying device without the support pattern 215b, i.e., the power rectifying device of FIG. 10. A reference numeral ‘15’ shows a turn-on characteristic and a turn-off characteristic of the power rectifying device having the residual support pattern 215r, i.e., the power rectifying device of FIG. 11. As illustrated in FIGS. 14A and 14B, the turn-on characteristic and the turn-off characteristic of the power rectifying device may be varied b the residual support pattern 215r. As a result, the electrical characteristics of the power rectifying device can be controlled by the residual support pattern 215r.

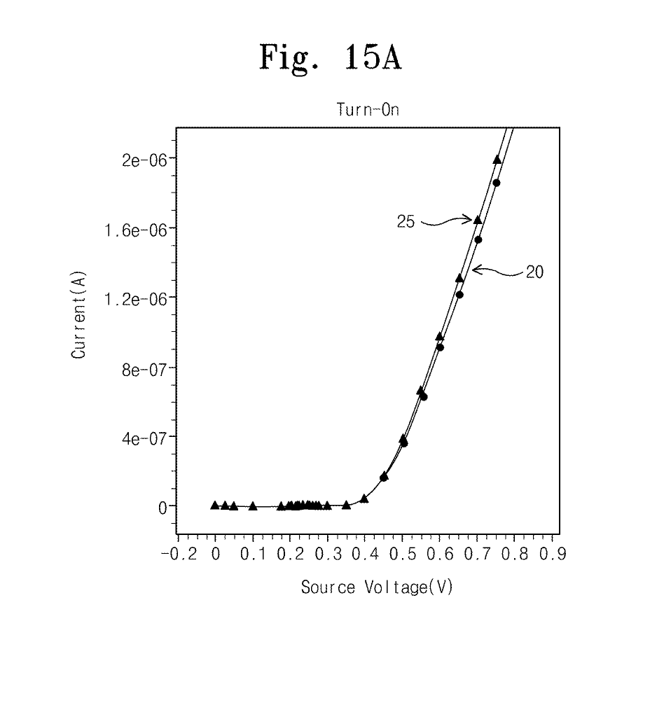

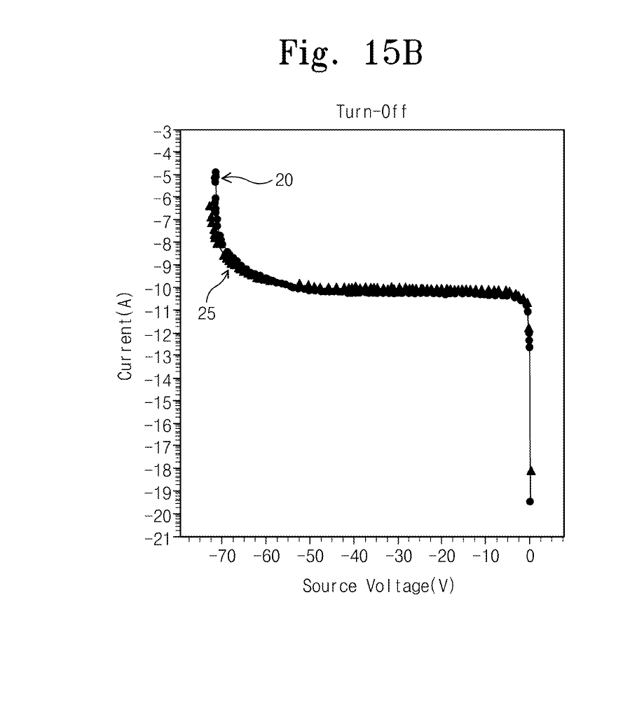

FIGS. 15A and 15B are graphs illustrating a turn-on characteristic and a turn-off characteristic related to a surface doped region in a power rectifying device according to other embodiments of the inventive concept, respectively.

Referring to FIGS. 15A and 15B, a reference numeral ‘25’ shows a turn-on characteristic and a turn-off characteristic of the power rectifying device including the surface doped region 250, and a reference numeral ‘20’ shows a turn-on characteristic and a turn-off characteristic of the power rectifying device without the surface doped region 250. As illustrated in FIGS. 15A and 15B, the electrical characteristics of the power rectifying device can be controlled by the surface doped region 250.

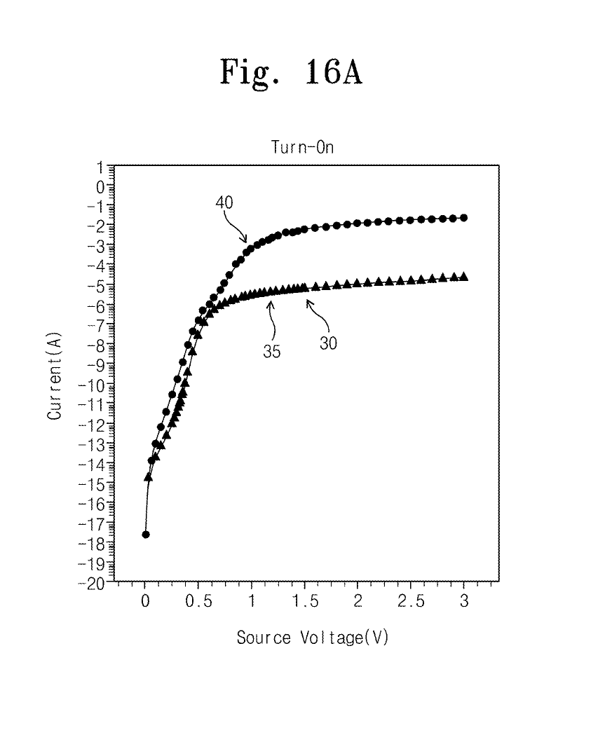

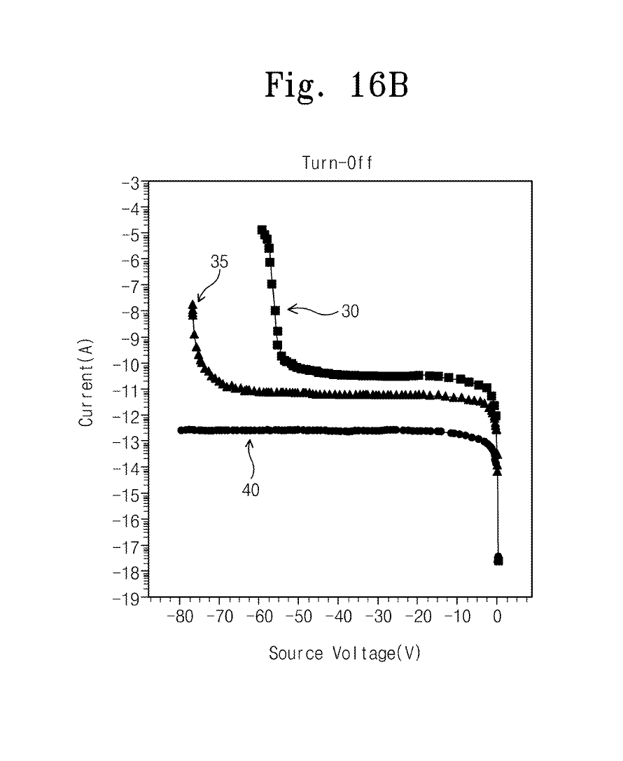

FIGS. 16A and 16B are graphs illustrating a turn-on characteristic and a turn-off characteristic related to a height of a top surface of a guarding region in a power rectifying device according to other embodiments of the inventive concept, respectively.

Referring to FIGS. 16A and 16B, a reference numeral ‘30’ shows a turn-on characteristic and a turn-off characteristic of the power rectifying device including the guarding region 225a having the top surface disposed at substantially the same height as the top surface of the source region 245b. A reference numeral ‘35’ shows a turn-on characteristic and a turn-off characteristic of the power rectifying device including the guarding region 225a having the top surface which is recessed to be lower by about 0.1 μm than the top surface of the source region 245b. A reference numeral ‘40’ shows a turn-on characteristic and a turn-off characteristic of the power rectifying device including the guarding region 225a having the top surface which is recessed to be lower by about 0.5 μm than the top surface of the source region 245b. As illustrated in FIGS. 16A and 16B, the electrical characteristics of the power rectifying device may be controlled according to a recessed depth of the top surface of the guarding region 225a.

### Third Embodiment

A power rectifying device according to the present embodiment is similar to the power rectifying device according to the first embodiment. Thus, in the present embodiment, the same elements as described in the first embodiment will be indicated by the same reference numerals or the same reference designators. For the purpose of ease and convenience in explanation, the descriptions to the same elements as in the first embodiment will be omitted or mentioned briefly. That is, differences between the present embodiment and the first embodiment will be mainly described hereinafter.

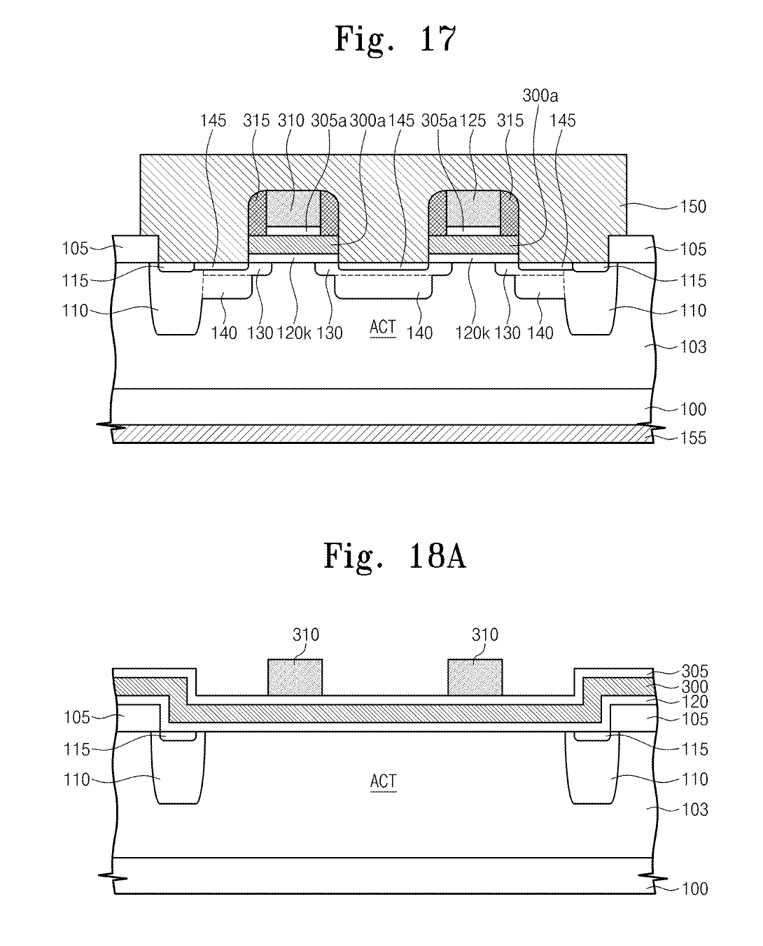

FIG. 17 is a cross-sectional view illustrating a modified example of a power rectifying device according to still other embodiments of the inventive concept.

Referring to FIG. 17, a first gate electrode 300a may be disposed over the active region ACT. A gate dielectric pattern 120k may be disposed between the first gate electrode 300a and the active region ACT. The gate dielectric pattern 120k may have both sidewalls aligned with both sidewalls of the first gate electrode 300a, respectively. A pedestal pattern 310 may be disposed on the first gate electrode 300a. The pedestal pattern 310 has a width smaller than a width of the first gate electrode 300a. The pedestal pattern 310 may be disposed on a center portion of a top surface of the first gate electrode 300a.

A second gate electrode 315 is disposed on each sidewall of the pedestal pattern 310. Additionally, the second gate electrode 315 is disposed on an edge of the top surface of the first gate electrode 300a. The second gate electrode 315 is connected to the top surface of the first gate electrode 300a. The second gate electrode 315 may be in contact with the edge of the top surface of the first gate electrode 300a.

The second gate electrode 315 has a first sidewall adjacent to the sidewall of the pedestal pattern 310 and a second sidewall opposite to the first sidewall. The first sidewall of the second gate electrode 315 may be substantially vertically flat, and the second sidewall of the second gate electrode 315 may include a rounded portion. In other words, the second gate electrode 315 may have a spacer-shape. The first gate electrode 300a has a sidewall aligned with the second sidewall of the second gate electrode 315.

The first body region 130 is disposed in the active region ACT at each side of the pedestal pattern 310. The first body region 130 may have a sidewall aligned with the sidewall of the pedestal pattern 310. An edge portion of the first gate electrode 300a may overlap with a portion of the first body region 130, and the second gate electrode 315 is disposed over the first body region 130.

The pedestal pattern 310 may be formed of a conductive material. For example, the pedestal pattern 310 may include at least one of a doped poly-silicon, a metal (e.g., tungsten, aluminum, titanium, and/or tantalum), and a conductive metal nitride (e.g., titanium nitride, tantalum nitride, and/or tungsten nitride). Alternatively, the pedestal pattern 310 may include a dielectric material such as an oxide (e.g., silicon oxide), a nitride (e.g., silicon nitride), and/or an oxynitride (e.g., silicon oxynitride).

The first gate electrode 300a and the second gate electrode 315 may be formed of the same materials as the first gate electrode 125 and the second gate electrode 135 of FIG. 1, respectively.

An etch stop pattern 305a may be disposed between the pedestal pattern 310 and the first gate electrode 300a. The etch stop pattern 305a may have both sidewalls respectively aligned with the both sidewalls of the pedestal pattern 310. The etch stop pattern 305a may include a dielectric material having an etch selectivity with respect to the pedestal pattern 310. For example, the etch stop pattern 305a may include an oxide (e.g., silicon oxide), a nitride (e.g., silicon nitride), and/or an oxynitride (e.g., silicon oxynitride). In another embodiment, the etch stop pattern 305a may be omitted.

The first electrode 150 is connected to the first and second gate electrodes 300a and 315, the pedestal pattern 310, the source region 145, and the pickup region 115.

The modified examples of the first embodiment may be applied to the power rectifying device under a non-contradictable condition.

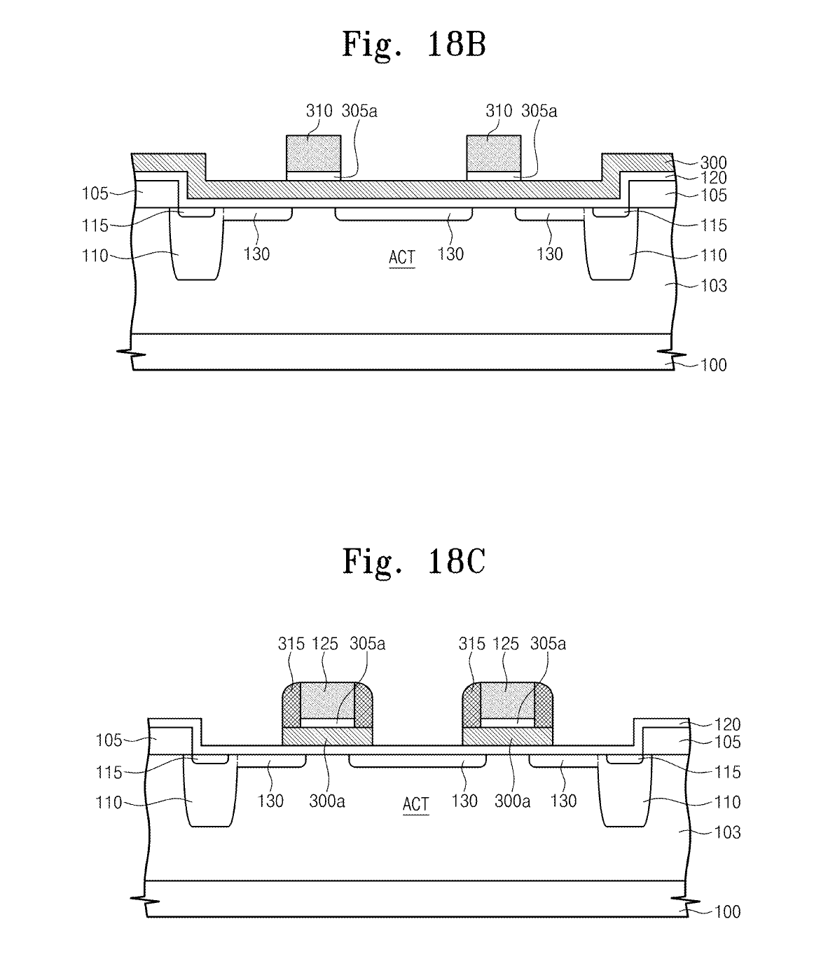

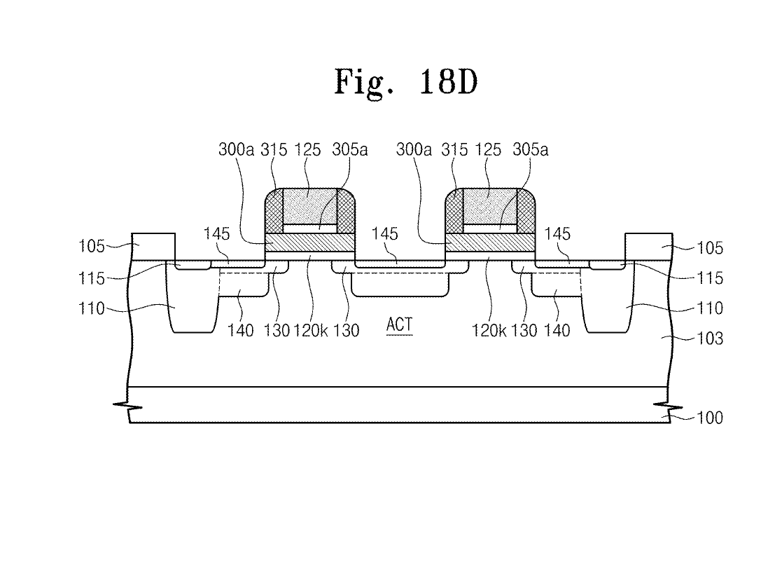

FIGS. 18A to 18D are cross-sectional views illustrating a method of manufacturing a power rectifying device according to still other embodiments of the inventive concept. A manufacturing method according to the present embodiment may include the processes described with reference to FIGS. 4A to 4C.

Referring to FIGS. 4C and 18A, a first gate layer 300 may be formed on the gate dielectric layer 120. The first gate layer 300 is formed of a conductive material (e.g., a doped poly-silicon).

An etch stop layer 305 may be formed on the first gate layer 300. A pedestal pattern 310 may be formed on the etch stop layer 305. The pedestal pattern 310 is disposed over the active region ACT. The etch stop layer 305 may protect the first gate layer 300 during a patterning process for the formation of the pedestal pattern 310.

Referring to FIG. 18B, the etch stop layer 305 may be etched using the pedestal pattern 310 as an etch mask, thereby forming an etch stop pattern 305a.

Dopant ions of the second conductivity type may be implanted using the pedestal pattern 310 as an ion implantation mask into the active region ACT, thereby forming a first body region 130.

In an embodiment, the first body region 130 and the second body region 140a may be sequentially formed as illustrated in FIG. 9A. Thus, widths of the first and second body regions 130 and 140a may be substantially equal to each other.

Referring to FIG. 18C, a second gate layer may be conformally formed on the substrate and then an etch-back process may be performed on the second gate layer. Thus, a gate electrode 315 is formed on each sidewall of the pedestal pattern 310. Subsequently, the first gate layer 300 may be etched to form a gate electrode 300a. The gate electrode 300a formed from the first gate layer 300 is defined as a first gate electrode 300a, and the gate electrode 315 formed from the second gate layer is defined as a second gate electrode 315.

Referring to FIG. 18D, the second body region 140 may be formed using the second gate electrode 315 and the pedestal pattern 310 as ion implantation masks. Also, the source region 145 may be formed using the second gate electrode 315 and the pedestal pattern 310 as ion implantation masks. The source region 145 may be formed by the methods described with reference to FIG. 4G.

The gate dielectric layer 120 at both sides of the first gate electrode 300a may be removed to expose the active region ACT. At this time, a gate dielectric pattern 120k may be formed under the first gate electrode 300a. Subsequently, the first and second electrodes 150 and 155 of FIG. 17 may be formed to realize the power rectifying device of FIG. 17.

In some embodiments, the power rectifying device may include the transistor structure including the first and second gate electrodes, the source region and the drain region. If a forward voltage is applied between the first and second terminals of the power rectifying device, the channel region of the transistor structure may be turned-on. Thus, the forward turn-on voltage of the power rectifying device may be reduced. Additionally, the power rectifying device is the current conduction device using the major carriers of the transistor structure, such that the reverse recovery time of the power rectifying device is short. As a result, the power rectifying device may have the fast switching speed, the low leakage current, and the excellent thermal reliability at a high temperature.

Additionally, the second gate electrode may be formed by performing the etch-back process on the gate layer deposited on the substrate having the first gate electrode. Thus, the channel length of the channel region under the second gate electrode may be determined depending on the thickness of the gate layer for the second gate electrode, and the channel region having a short channel length may be formed. As a result, it is possible to realize the power rectifying device of which the turn-on voltage is low.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A power rectifying device comprising:
a substrate doped with dopants of a first conductivity type;
a first gate electrode disposed on the substrate;
a first body region formed in the substrate at a side of the first gate electrode, the first body region doped with dopants of a second conductivity type different from the first conductivity type;
a second gate electrode disposed on a sidewall of the first gate electrode and on the first body region; and
a source region formed in the first body region at a side of the second gate electrode, the source region doped with dopants of the first conductivity type,
wherein the first gate electrode, the second gate electrode, the first body region, and the source region are connected in common to a first terminal; and
wherein the substrate under the first gate electrode is connected to a second terminal.

2. The power rectifying device of claim 1, further comprising:
a gate dielectric pattern disposed between the first gate electrode and the substrate and between the second gate electrode and the substrate,
wherein the second gate electrode is in contact with the sidewall of the first gate electrode.

3. The power rectifying device of claim 1, further comprising:
a first gate dielectric pattern disposed between the first gate electrode and the substrate; and
a second gate dielectric pattern disposed between the second gate electrode and the substrate,
wherein the second gate dielectric pattern extends between first gate electrode and the second gate electrode.

4. The power rectifying device of claim 1, further comprising:
a dielectric-spacer disposed between the first and second gate electrodes;
a first gate dielectric pattern disposed between the first gate electrode and the substrate; and
a second gate dielectric pattern disposed between the second gate electrode and the substrate,
wherein the dielectric-spacer includes a different dielectric material from the first and second gate dielectric patterns.

5. The power rectifying device of claim 4, wherein the first gate dielectric pattern laterally extends to be disposed between the dielectric-spacer and the substrate.

6. The power rectifying device of claim 4, wherein the dielectric-spacer extends downward to be disposed between the first and second gate dielectric patterns.

7. The power rectifying device of claim 1, wherein a top surface of the first gate electrode is lower than a top end of the second gate electrode.

8. The power rectifying device of claim 1, further comprising:
a second body region disposed in the substrate under the first body region,
wherein the second body region is doped with dopants of the second conductivity type.

9. The power rectifying device of claim 8, wherein the second gate electrode has a first sidewall adjacent to the first gate electrode and a second sidewall opposite to the first sidewall; and
wherein the second body region has a sidewall aligned with the second sidewall of the second gate electrode.

10. The power rectifying device of claim 8, wherein the second body region has a sidewall aligned with the sidewall of the first gate electrode.

11. The power rectifying device of claim 1, wherein the second gate electrode is formed by performing an etch-back process on a gate layer deposited on the substrate having the first gate electrode.

12. A power rectifying device comprising:
a substrate doped with dopants of a first conductivity type;
a first gate electrode disposed on the substrate;
a gate dielectric pattern disposed between the first gate electrode and the substrate;
a pedestal pattern disposed on a top surface of the first gate electrode;
a first body region disposed in the substrate at a side of the pedestal pattern, the first body region doped with dopants of a second conductivity type different from the first conductivity type;
a second gate electrode disposed on a sidewall of the pedestal pattern and on an edge of the top surface of the first gate electrode, the second gate electrode disposed over the first body region; and
a source region disposed in the first body region at a side of the second gate electrode, the source region doped with dopants of the first conductivity type,
wherein the first and second gate electrodes, the first body region, and the source region are connected in common to a first terminal; and
wherein the substrate under the first gate electrode is connected to a second terminal.

13. The power rectifying device of claim 12, wherein the second gate electrode has a first sidewall adjacent to the pedestal and a second sidewall opposite to the first sidewall; and
wherein the first gate electrode has a sidewall aligned with the second sidewall of the second gate electrode.

14. The power rectifying device of claim 12, wherein the second gate electrode is in contact with the edge of the top surface of the first gate electrode.

15. The power rectifying device of claim 12, further comprising:
an etch stop pattern disposed between the pedestal pattern and the first gate electrode,
wherein the etch stop pattern is formed of a dielectric material having an etch selectivity with respect to the pedestal pattern.

16. The power rectifying device of claim 12, further comprising:
a second body region formed in the substrate under the first body region,
wherein the second body region is doped with dopants of the second conductivity type.

17. The power rectifying device of claim 12, wherein the second gate electrode is formed by performing an etch-back process on a gate layer deposited on the substrate having the first gate electrode.

18. A power rectifying device comprising:
a substrate doped with dopants of a first conductivity type;
an etch stop pattern disposed on the substrate;
a body region disposed in the substrate at a side of the etch stop pattern, the body region doped with dopants of a second conductivity type different from the first conductivity type;
a gate electrode disposed on a sidewall of the etch stop pattern and on the body region;
a gate dielectric pattern disposed between the gate electrode and the body region; and
a source region disposed in the body region at a side of the gate electrode, the source region doped with dopants of the first conductivity type,
wherein the gate electrode, the body region, and the source region are connected in common to a first terminal;
wherein the substrate under the etch stop pattern is connected to a second terminal;
wherein the gate electrode has a first sidewall adjacent to the sidewall of the etch stop pattern, and a second sidewall opposite to the first sidewall;
wherein the second sidewall of the gate electrode includes a rounded portion; and
wherein a top end of the gate electrode is higher than a top surface of the etch stop pattern.

19. The power rectifying device of claim 18, further comprising:
a surface doped region formed in the substrate under the etch stop pattern,
wherein the surface doped region is doped with dopants of the first conductivity type; and
wherein a dopant concentration of the surface doped region is greater than a dopant concentration of the substrate directly beneath the surface doped region.

20. The power rectifying device of claim 18, further comprising:
a guarding region formed in the substrate at a side of the source region,
wherein the guarding region is doped with dopants of the second conductivity type;
wherein the body region is connected to the guarding region; and
wherein a top surface of the guarding region is recessed to be lower than a top surface of the source region.
